(19) United States
(12) Patent Application Publication
(10) Pub. No.: US 2019/0339619 A1
(43) Pub. Date: Nov. 7, 2019

(54) CHEMICAL LIQUID MANUFACTURING METHOD AND CHEMICAL LIQUID MANUFACTURING DEVICE

(71) Applicant: FUJIFILM Corporation, Tokyo (JP)

(72) Inventor: Tetsuya KAMIMURA, Shizuoka (JP)

(73) Assignee: FUJIFILM Corporation, Tokyo (JP)

(21) Appl. No.: 16/510,986

(22) Filed: Jul. 15, 2019

Related U.S. Application Data
(63) Continuation of application No. PCT/JP2018/000741, filed on Jan. 15, 2018.

(30) Foreign Application Priority Data
Feb. 1, 2017 (JP) 2017-016823

(51) Int. Cl. G03F 7/32; B01D 29/62; B01D 15/36; B01D 36/00; G03F 7/004; H01L 21/027

(52) U.S. Cl. CPC G03F 7/32; B01D 29/62; H01L 21/0274; B01D 36/00; G03F 7/004; B01D 15/361

(57) ABSTRACT

An object of the present invention is to provide a chemical liquid manufacturing method which makes it possible to manufacture a chemical liquid having an excellent defect inhibition performance. The chemical liquid manufacturing method of an embodiment of the present invention is a method for manufacturing a chemical liquid containing an organic solvent by using a manufacturing device. The chemical liquid manufacturing method has a setup step including a step A of washing the manufacturing device by using a washing solution and a step B of extracting the washing solution from the manufacturing device and a preparation step of preparing the chemical liquid in the manufacturing device, in which in the setup step, the step A and the step B are repeatedly performed until the washing solution extracted from the manufacturing device satisfies the following condition 1 after the step A and the step B.

Condition 1: in a case where a substrate is coated with the washing solution, a change in density of particles, which have a particle diameter equal to or smaller than 20 nm, on the substrate before and after the coating with the washing solution is equal to or smaller than 0.5 particles/cm2.

### CROSS-REFERENCE TO RELATED APPLICATIONS

This application is a Continuation of PCT International Application No. PCT/JP2018/000741 filed on Jan.15, 2018, which claims priority under 35 U.S.C. § 119(a) to Japanese Patent Application No. 2017-016823 filed on Feb. 1, 2017. The above application is hereby expressly incorporated by reference, in its entirety, into the present application.

### BACKGROUND OF THE INVENTION

### 1. Field of the Invention

The present invention relates to a chemical liquid manufacturing method and a chemical liquid manufacturing device.

### 2. Description of the Related Art

For manufacturing a semiconductor device, a photolithography method is used. In the photolithography method, a substrate such as a semiconductor wafer (hereinafter, referred to as “wafer” as well) is pre-wetted, and then coated with an actinic ray-sensitive or radiation-sensitive resin composition (hereinafter, referred to as “resist composition” as well) so as to form a resist film. Furthermore, by exposing the formed resist film, developing the exposed resist film, and rinsing the developed resist film, a resist pattern is formed on the wafer.

In recent years, as semiconductor devices have been further scaled down, the inhibition of the occurrence of a defect in the photolithography method has been required. Specifically, there has been a demand for a chemical liquid that can further inhibit the occurrence of a defect on a wafer in each of the processes such as pre-wetting, resist film formation, development, and rinsing.

JP2012-047896A describes a pattern forming method using a developer, in which density of particles having a particle diameter equal to or greater than 0.3 μm is equal to or lower than 30 particles/mL, and a rinsing solution.

### SUMMARY OF THE INVENTION

The inventors of the present invention conducted examinations regarding the developer and the rinsing solution described in JP2012-047896A. As a result, it has been revealed that, unfortunately, the defect inhibition performance does not reach the currently required level.

Therefore, an object of the present invention is to provide a chemical liquid manufacturing method which makes it possible to manufacture a chemical liquid having an excellent defect inhibition performance (hereinafter, described as “having the effects of the present invention” as well).

In order to achieve the object, the inventors of the present invention conducted intensive examinations. As a result, they have found that the object can be achieved by the following constitution.

[1] A chemical liquid manufacturing method for manufacturing a chemical liquid containing an organic solvent by using a manufacturing device, the method including a setup step, which has a step A of washing the manufacturing device by using a washing solution and a step B of extracting the washing solution from the manufacturing device, and a preparation step of preparing the chemical liquid in the manufacturing device, in which in the setup step, the step A and the step B are repeatedly performed until the washing solution extracted from the manufacturing device satisfies the following condition 1 after the step A and the step B.

Condition 1: in a case where a substrate is coated with the washing solution, a change in density of particles, which have a particle diameter equal to or smaller than 20 nm, on the substrate before and after the coating with the washing solution is equal to or smaller than 0.5 particles/cm².

[2] The chemical liquid manufacturing method described in [1], in which in the setup step, the step A and the step B are repeatedly performed until the washing solution extracted from the manufacturing device further satisfies the following additional condition 2.

Additional condition 2: in a case where a substrate is coated with the washing solution, a change in density of particles, which have a particle diameter greater than 20 nm and equal to or smaller than 100 nm, on the substrate before and after the coating with the washing solution is equal to or smaller than 0.04 particles/cm².

[3] The chemical liquid manufacturing method described in [1] or [2], in which the manufacturing device comprises a tank, a liquid contact portion in the tank is formed of electropolished stainless steel, and a content mass ratio of a content of Cr to a content of Fe in the liquid contact portion is higher than 0.5 and lower than 3.5.

[4] The chemical liquid manufacturing method described in any one of [1] to [3], in which in the setup step, the step A and the step B are repeatedly performed until the washing solution extracted from the manufacturing device further satisfies the following additional condition 3.

Additional condition 3: in the washing solution, a content of each of impurity metals containing Fe, Cr, Pb, and Ni is 0.001 to 10 mass ppt.

[5] The chemical liquid manufacturing method described in any one of [1] to [4], in which in the setup step, the step A and the step B are repeatedly performed until the washing solution extracted from the manufacturing device further satisfies the following additional condition 4.

Additional condition 4: in the washing solution, a content of an organic impurity having a boiling point equal to or higher than 250° C. is 0.001 to 10 mass ppm.

[6] The chemical liquid manufacturing method described in [5], in which the organic impurity contains at least one kind of compound selected from the group consisting of Formulae (1) to (7).

[7] The chemical liquid manufacturing method described in any one of [1] to [6], in which the manufacturing device comprises a filtering device, the washing solution having been used in the step A is filtered through the filtering device at the time of repeatedly performing the step A and the step B in the setup step, and the filtered washing solution is reused in a new step A.

[8] The chemical liquid manufacturing method described in [7], in which the filtering device includes at least one kind of filtering member selected from the group consisting of a filter for removing particles having a diameter equal to or smaller than 20 nm and a metal ion adsorption member.

[9] The chemical liquid manufacturing method described in [8], in which the filtering member includes a filter for removing particles having a diameter equal to or smaller than 20 nm and a metal ion adsorption member.

[10] The chemical liquid manufacturing method described in [8] or [9], in which the metal ion adsorption member includes a metal ion adsorption filter capable of performing ion exchange, and the metal ion adsorption filter contains an acid group on a surface thereof.

[11] The chemical liquid manufacturing method described in any one of [1] to [10], in which a difference between a contribution rate of Hansen solubility parameters of the washing solution and a contribution rate of Hansen solubility parameters of the organic solvent is 0 to 30.

[12] The chemical liquid manufacturing method described in any one of [1] to [11], in which the chemical liquid is at least one kind of chemical liquid selected from the group consisting of a prewet solution, a developer, and a solvent contained in an actinic ray-sensitive or radiation-sensitive composition.

[13] A chemical liquid manufacturing device for manufacturing a chemical liquid containing an organic solvent, the device comprising a tank which stores the organic solvent, a filtering portion which is connected to the tank through a supply pipe line and filters the organic solvent discharged from the tank, a circulation pipe line through which the organic solvent discharged from the filtering portion is stored in the tank, a discharge portion which is provided in the circulation pipe line and discharges the chemical liquid, and a washing solution monitoring portion which is provided in at least one site selected from the group consisting of the tank, the supply pipe line, and the circulation pipe line so as to extract at least a portion of a washing solution for washing the manufacturing device.

According to the present invention, a chemical liquid manufacturing method which makes it possible to manufacture a chemical liquid having an excellent defect inhibition performance can be provided.

### BRIEF DESCRIPTION OF THE DRAWINGS

FIG. 1 is a schematic view showing an aspect of a manufacturing device which can be used in a chemical liquid manufacturing method according to an embodiment of the present invention.

FIG. 2 is a schematic view showing another aspect of the manufacturing device which can be used in the chemical liquid manufacturing method according to the embodiment of the present invention.

FIG. 3 is a ternary diagram with apexes each showing a contribution rate of a dispersion element in Hansen solubility parameters, a contribution rate of a dipole-dipole force element in Hansen solubility parameters, and a contribution rate of a hydrogen bond element in Hansen solubility parameters.

FIG. 4 is a flowchart showing a chemical liquid manufacturing method according to an embodiment of the present invention having a first checking step.

FIG. 5 is a flowchart showing the chemical liquid manufacturing method according to another embodiment of the present invention having a second checking step.

FIG. 6 is a flowchart showing the chemical liquid manufacturing method according to the embodiment of the present invention having the second checking step.

FIG. 7 is a flowchart showing the chemical liquid manufacturing method according to the embodiment of the present invention having a third checking step.

FIG. 8 is a flowchart showing the chemical liquid manufacturing method according to another embodiment of the present invention having the third checking step.

FIG. 9 is a flowchart showing the chemical liquid manufacturing method according to the embodiment of the present invention having a fourth checking step.

FIG. 10 is a flowchart showing the chemical liquid manufacturing method according to another embodiment of the present invention having the fourth checking step.

### DESCRIPTION OF THE PREFERRED EMBODIMENTS

Hereinafter, the present invention will be specifically described.

The following constituents will be described based on typical embodiments of the present invention in some cases, but the present invention is not limited to the embodiments.

In the present specification, a range of numerical values described using “to” means a range including the numerical values listed before and after “to” as a lower limit and an upper limit respectively.

In the present invention, “preparation” means not only the preparation of a specific material by means of synthesis or mixing but also the preparation of a predetermined substance by means of purchase and the like.

In the present invention, “ppm” means “parts-per-million (10⁻⁶)”, “ppb” means “parts-per-billion (10⁻⁹)”, “ppt” means “parts-per-trillion (10⁻¹²)”, and “ppq” means “parts-per-quadrillion (10⁻¹⁵)”.

In the present invention, 1 Å (angstrom) equals 0.1 nm.

In the present invention, regarding the description of a group (atomic group), in a case where whether the group is substituted or unsubstituted is not described, as long as the effects of the present invention are not impaired, the group includes a group which does not have a substituent and a group which has a substituent. For example, “hydrocarbon group” includes not only a hydrocarbon group which does not have a substituent (unsubstituted hydrocarbon group) but also a hydrocarbon group which has a substituent (substituted hydrocarbon group). The same is true for each compound.

Furthermore, in the present invention, “radiation” means, for example, far ultraviolet rays, extreme ultraviolet (EUV), X-rays, electron beams, and the like. In addition, in the present invention, light means actinic rays or radiation. In the present invention, unless otherwise specified, “exposure” includes not only exposure, far ultraviolet rays, X-rays, and EUV, and the like, but also lithography by particle beams such as Electron beams or ion beams.

### Chemical Liquid Manufacturing Method

The chemical liquid manufacturing method according to an embodiment of the present invention is a chemical liquid manufacturing method for manufacturing a chemical liquid containing an organic solvent by using a manufacturing device. The manufacturing method has the following steps.
Setup step
Preparation step

Furthermore, the setup step has the following steps.
Step A of washing manufacturing device by using washing solution
Step B of extracting washing solution from manufacturing device

In the setup step, the step A and the step B are repeatedly performed until the washing solution extracted from the manufacturing device satisfies a condition 1 after the step A and the step B.

The condition 1 is as below.

Condition 1: in a case where a substrate is coated with the washing solution, a change in density of particles, which have a particle diameter equal to or smaller than 20 nm, on the substrate before and after the coating with the washing solution is equal to or smaller than 0.5 particles/cm².

The inventors of the present invention know that in the field of chemical liquids used for semiconductor manufacturing process requiring high purity, it is important to reduce the number of particles having a diameter equal to or smaller than 20 nm on a substrate. Based on this knowledge, the present invention has been accomplished.

By the chemical liquid manufacturing method according to the embodiment of the present invention, the manufacturing device is washed in advance with a washing solution so as to remove particles having a diameter equal to or smaller than 20 nm. Therefore, the manufacturing method can provide a chemical liquid having an excellent defect inhibition performance.

Hereinafter, the chemical liquid will be described first, then the manufacturing device will be described using drawings, and then the chemical liquid manufacturing method will be described regarding each step.

### Chemical Liquid

The chemical liquid contains an organic solvent. The content of the organic solvent in the chemical liquid is not particularly limited. Generally, the content of the organic solvent with respect to the total mass of the chemical liquid is preferably 97.0% to 99.999% by mass, and more preferably 99.9% to 99.999% by mass. One kind of organic solvent may be used singly, or two or more kinds of solvents may be used in combination. In a case where two or more kinds of organic solvents are used in combination, the total content thereof is preferably within the above range.

In the present specification, an organic solvent means one liquid organic compound which is contained in the chemical liquid in an amount greater than 10,000 mass ppm with respect to the total mass of the chemical liquid. That is, in the present specification, a liquid organic compound contained in the chemical liquid in an amount greater than 10,000 mass ppm with respect to the total mass of the chemical liquid corresponds to an organic solvent.

In the present specification, “liquid” means that the compound stays in liquid form at 25° C. under atmospheric pressure.

The type of the organic solvents is not particularly limited, and known organic solvents can be used. Examples of the organic solvents include alkylene glycol monoalkyl ether carboxylate, alkylene glycol monoalkyl ether, a lactic acid alkyl ester, alkoxyalkyl propionate, cyclic lactone (preferably having 4 to 10 carbon atoms), a monoketone compound which may have a ring (preferably having 4 to 10 carbon atoms), alkylene carbonate, alkoxyalkyl acetate, alkyl pyruvate, and the like.

Furthermore, as the organic solvents, those described in JP2016-057614A, JP2014-219664A, JP2016-138219A, and JP2015-135379A may be used.

The chemical liquid preferably contains at least one kind of organic solvent selected from the group consisting of propylene glycol monomethyl ether (PGME), cyclopentanone (CyPn), cyclopentane (CyPe), butyl acetate (nBA), propylene glycol monomethyl ether acetate (PGMEA), cyclohexane (CyHe), cyclohexanone (CyHx), ethyl lactate (EL), 2-hydroxymethyl isobutyrate (HBM), cyclopentanone dimethyl acetal (DBCPN), y-butyrolactone (GBL), dimethyl sulfoxide (DMSO), ethylene carbonate (EC), propylene carbonate (PC), 1-methyl-2-pyrrolidone (NMP), isoamyl acetate (iAA), 2-propanol (IPA), methyl ethyl ketone (MEK), and 4-methyl-2-pentanol (MIBC), and more preferably contains at least one kind of organic solvent selected from the group consisting of PGMEA, MIBC, nBA, PGME, CyHe, GBL, EL, DMSO, iAA, HBM, PC, and CyPe. One kind of organic solvent may be used singly, or two or more kinds of organic solvents may be used in combination.

The chemical liquid may contain other components in addition to the organic solvent. Examples of those other components include a metal impurity, an organic impurity, a surfactant, water, and the like.

### Manufacturing Device

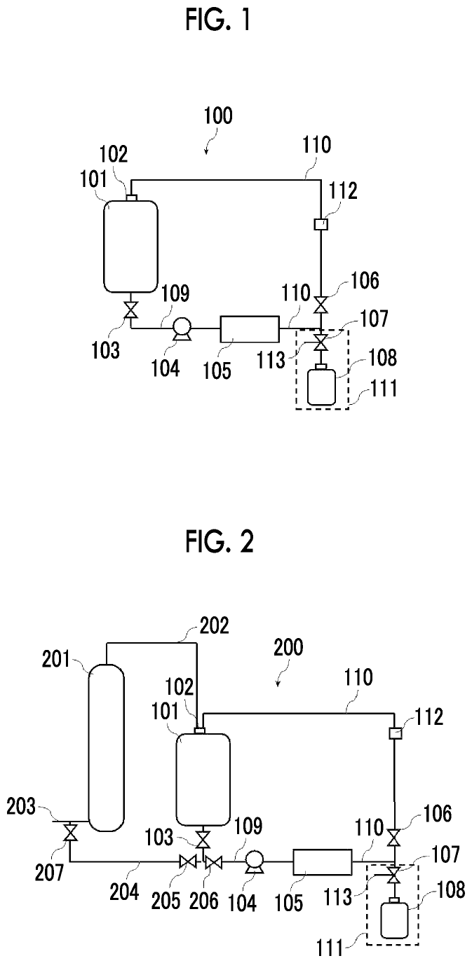

FIG. 1 is a schematic view showing an aspect of a manufacturing device which can be used in the chemical liquid manufacturing method according to an embodiment of the present invention. A manufacturing device 100 comprises a tank 101, and the tank 101 comprises a supply port 102 for supplying a washing solution, which will be described later, and/or an organic solvent. The manufacturing device 100 comprises a filtering device 105. The tank 101 and the filtering device 105 are connected to each other through a supply pipe line 109 such that a fluid (the washing solution, the organic solvent, the chemical liquid, or the like) can be transferred between the tank 101 and the filtering device 105. In the supply pipe line 109, a valve 103 and a pump 104 are disposed. The manufacturing device 100 shown in FIG. 1 comprises the tank 101 and the filtering device 105. However, the manufacturing device which can be used in the chemical liquid manufacturing method according to the embodiment of the present invention is not limited thereto.

In the manufacturing device 100, the fluid supplied from the supply port 102 passes through the valve 103 and the pump 104 and flows into the filtering device 105. The fluid discharged from the filtering device 105 passes through a circulation pipe line 110 and stored in the tank 101.

The manufacturing device 100 comprises a discharge portion 111 discharging the chemical liquid to the circulation pipe line 110. The discharge portion 111 comprises a valve 107 and a container 108, and is constituted such that the manufactured chemical liquid can be stored into the container 108 by the switching between a valve 106 provided in the circulation pipe line and the valve 107. The valve 107 is connected to a switchable pipe line 113. Through the pipe line 113, the washing solution having been used for circulation washing can be discharged out of the manufacturing device 100. The washing solution having been used for circulation washing contains particles, metal impurities, and the like in some cases. By the manufacturing device 100 comprising the pipe line 113 discharging the washing solution to the out of the device, it is possible to obtain a chemical liquid having a further improved defect inhibition performance without contaminating a filling portion of the container 108 or the like.

Furthermore, the manufacturing device 100 comprises a washing solution monitoring portion 112 in the circulation pipe line 110. Although the manufacturing device 100 in FIG. 1 comprises the washing solution monitoring portion 112 in the circulation pipe line 110, the manufacturing device which can be used in the chemical liquid manufacturing method according to the embodiment of the present invention is not limited thereto. The washing solution monitoring portion 112 may be provided in the supply pipe line 109 or in the supply pipe line 109 and the circulation pipe line 110. In the manufacturing device 100, the washing solution monitoring portion 112 is provided directly in the circulation pipe line 110. However, the manufacturing device which can be used in the chemical liquid manufacturing method according to the embodiment of the present invention is not limited thereto. The washing solution monitoring portion may be provided in the tank 101. In a case where the valve 106 is a switchable valve, the washing solution monitoring portion may be provided in a pipe line not shown in the drawing that branches off the valve 106. Alternatively, the washing solution monitoring portion may be provided in a temporary storage tank (different from the tank 101) for a fluid not shown in the drawing that is provided in a pipe line. In view of obtaining a chemical liquid further inhibited from undergoing intermixing of impurities from the environment, the washing solution monitoring portion is preferably in a clean environment (a clean room, a clean booth, or the like). In view of making it easy for the washing solution monitoring portion to be in a clean environment, in the manufacturing device 100, the washing solution monitoring portion is more preferably provided in the circulation pipe line 110 or in the temporary storage tank for a fluid not shown in the drawing that is provided in a pipe line. In the manufacturing device 100, the washing solution monitoring portion is more preferably provided in the pipe line 113 of the discharge portion 111, because then the monitoring portion is close to the purified chemical liquid, and the amount of impurities can be accurately evaluated.

FIG. 2 is a schematic view showing another aspect of the manufacturing device which can be used in the chemical liquid manufacturing method according to the embodiment of the present invention. The manufacturing device 200 comprises a tank 101, a filtering device 105, and a distillation column 201 which is connected to the tank 101 through a pipe line 202, a pipe line 204, and a pipe line 203 and disposed such that a fluid can be transferred between the tank 101 and the distillation column 201 through the above pipe lines. The manufacturing device which can be used in the chemical liquid manufacturing method according to the embodiment of the present invention may not comprise the filtering device 105 and/or the distillation column 201. In addition, the manufacturing device may further comprise a reaction container connected to the distillation column 201 through the pipe line 203, and the like.

In the manufacturing device 200, a fluid supplied to the distillation column 201 through the pipe line 203 is distilled in the distillation column 201. The distilled fluid passes through the pipe line 202 and is stored into the tank 101. A supply pipe line 109 comprises a valve 103 and a valve 206 and is constituted such that the fluid, which is discharged from the tank 101 by the switching with a valve 205 provided in the pipe line 204, can flow into the filtering device 105.

In the manufacturing device 200, the fluid discharged from the tank 101 can also flow back into the distillation column 201. In this case, by the switching among the valve 103, the valve 206, and the valve 205, the fluid from the pipe line 204 passes through a valve 207 and the pipe line 203 and flows into the distillation column 201.

The material of a liquid contact portion (the definition of the liquid contact portion will be described later) of the manufacturing device is not particularly limited. In view of obtaining a chemical liquid having a further improved defect inhibition performance, the liquid contact portion is preferably formed of at least one kind of material selected from the group consisting of a nonmetallic material and an electropolished metallic material. In the present specification, “liquid contact portion” is a portion which is likely to contact a fluid (for example, the inner surface of the tank, the inner surface of the pipe line, or the like) and means an area ranging to a portion which is 100 nm below the surface thereof in a thickness direction.

As the metallic material, known materials can be used without particular limitation.

Examples of the metallic material include a metallic material in which the total content of chromium and nickel with respect to the total mass of the metallic material is greater than 25% by mass. The total content of chromium and nickel is more preferably equal to or greater than 30% by mass. The upper limit of the total content of chromium and nickel in the metallic material is not particularly limited, but is preferably equal to or smaller than 90% by mass in general.

Examples of the metallic material include stainless steel, a nickel-chromium alloy, and the like.

As the stainless steel, known stainless steel can be used without particular limitation. Among these, an alloy with a nickel content equal to or higher than 8% by mass is preferable, and austenite-based stainless steel with a nickel content equal to or higher than 8% by mass is more preferable. Examples of the austenite-based stainless steel include Steel Use Stainless (SUS) 304 (Ni content: 8% by mass, Cr content: 18% by mass), SUS304L (Ni content: 9% by mass, Cr content: 18% by mass), SUS316 (Ni content: 10% by mass, Cr content: 16% by mass), SUS316L (Ni content: 12% by mass, Cr content: 16% by mass), and the like.

As the nickel-chromium alloy, known nickel-chromium alloys can be used without particular limitation. Among these, a nickel-chromium alloy is preferable in which the nickel content is 40% to 75% by mass and the chromium content is 1% to 30% by mass with respect to the total mass of the metallic material.

Examples of the nickel-chromium alloy include HASTELLOY (trade name, the same is true for the following description), MONEL (trade name, the same is true for the following description), INCONEL (trade name, the same is true for the following description), and the like. More specifically, examples thereof include HASTELLOY C-276 (Ni content: 63% by mass, Cr content: 16% by mass), HASTELLOY C (Ni content: 60% by mass, Cr content: 17% by mass), HASTELLOY C-22 (Ni content: 61% by mass, Cr content: 22% by mass), and the like.

Furthermore, if necessary, the nickel-chromium alloy may further contain boron, silicon, tungsten, molybdenum, copper, cobalt, and the like in addition to the aforementioned alloy.

As the method for electropolishing the metallic material, known methods can be used without particular limitation. For example, it is possible to use the methods described in paragraphs “0011” to “0014” in JP2015-227501A, paragraphs “0036” to “0042” in JP2008-264929A, and the like.

Presumably, in a case where the metallic material is electropolished, the chromium content in a passive layer on the surface thereof may become higher than the chromium content in the parent phase. Presumably, for this reason, from the manufacturing device in which the liquid contact portion is formed of an electropolished metallic material, the metal impurity containing metal atoms may not easily flow into the organic solvent, and hence a chemical liquid having a further improved defect inhibition performance can be obtained.

The metallic material may have undergone buffing. As the buffing method, known methods can be used without particular limitation. The size of abrasive grains used for finishing the buffing is not particularly limited, but is preferably equal to or smaller than # 400 because such grains make it easy to further reduce the surface asperity of the metallic material. The buffing is preferably performed before the electropolishing.

In view of obtaining a chemical liquid having a further improved defect inhibition performance, the liquid contact portion is preferably formed of electropolished stainless steel. Particularly, in a case where the manufacturing device comprises a tank, the liquid contact portion of the tank is more preferably formed of electropolished stainless steel. The content mass ratio of a content of Cr to a content of Fe (hereinafter, referred to as “Cr/Fe” as well) in the liquid contact portion is not particularly limited. Generally, Cr/Fe is preferably 0.5 to 4. Particularly, in view of making it more difficult for the metal impurity and/or the organic impurity to be eluted into the chemical liquid, Cr/Fe is more preferably higher than 0.5 and lower than 3.5, and even more preferably equal to or higher than 0.7 and equal to or lower than 3.0. In a case where Cr/Fe is higher than 0.5, the elution of a metal from the interior of the tank is more easily inhibited. In a case where Cr/Fe is lower than 3.5, it becomes harder for the exfoliation of the liquid contact portion causing particles to occur.

The method for adjusting Cr/Fe in the metallic material is not particularly limited, and examples thereof include a method of adjusting the content of Cr atoms in the metallic material, a method of performing electropolishing such that the content of chromium in a passive layer on a polished surface becomes greater than the content of chromium in the parent phase, and the like.

### Filtering Device

It is preferable that the manufacturing device comprises a filtering device, because then a chemical liquid having a further improved defect inhibition performance is easily obtained. A filtering member that the filtering device includes is not particularly limited, but is preferably at least one kind of member selected from the group consisting of a filter having a pore size equal to or smaller than 20 nm and a metal ion adsorption member. It is more preferable that the filtering device includes both the filter having a pore size equal to or smaller than 20 nm and the metal ion adsorption member.

Filter having pore size equal to or smaller than 20 nm

The filter having a pore size equal to or smaller than 20 nm has a function of efficiently removing particles having a diameter larger than 20 nm from the organic solvent as is a raw material of the chemical liquid and the like.

The pore size of the filter is preferably 1 to 15 nm, and more preferably 1 to 12 nm. In a case where the pore size is equal to or smaller than 15 nm, finer particles can be removed. In a case where the pore size is equal to or greater than 1 nm, the filtering efficiency is further improved.

The pore size affects the minimum size of particles that the filter can remove. For example, in a case where the pore size of the filter is 20 nm, it is possible to remove particles having a diameter larger than 20 nm by a sieving effect. Furthermore, in some cases, due to the deposition of a cake on the filter or due to the adsorption of particles onto the filter, particles having a diameter equal to or smaller than 20 nm can also be removed.

Examples of materials of the filter include polyamide such as 6-nylon or 6,6-nylon, polyethylene, polypropylene, polystyrene, polyimide, polyamide imide, a fluororesin, and the like.

The polyimide and/or the polyamide imide may have at least one group selected from the group consisting of a carboxy group, a salt-type carboxy group, and a —NH—bond. The fluororesin and the polyimide and/or the polyamide imide have excellent in solvent resistance. Furthermore, from the viewpoint of adsorbing metal ions, polyamide such as 6-nylon or 6,6-nylon is preferable, and nylon is more preferable.

The filtering device may have a plurality of filters described above. In a case where the filtering device has a plurality of filters, as another filter, a filter having a pore size equal to or greater than 50 nm (for example, a microfiltration membrane for removing fine particles having a pore size equal to or greater than 50 nm) is preferable, but the filter is not particularly limited. In a case where fine particles are present in a substance to be purified in addition to a colloidized impurity, particularly, a colloidized impurity containing a metal atom such as iron or aluminum, by filtering the substance to be purified by using a filter having a pore size equal to or greater than 50 nm (for example, a microfiltration membrane for removing fine particles having a pore size equal to or greater than 50 nm) before filtering the substance to be purified by using a filter having a pore size equal to or smaller than 20 nm (for example, a microfiltration membrane having a pore size equal to or smaller than 20 nm), the filtering efficiency of the filter having a pore size equal to or smaller than 20 nm (for example, a microfiltration membrane having a pore size equal to or smaller than 20 nm) is improved, and the particle removing performance is further improved.

### Metal Ion Adsorption Filter

It is preferable that the filtering device has a metal ion adsorption filter.

The metal ion adsorption filter is not particularly limited, and examples thereof include and examples thereof include known metal ion adsorption filters.

The metal ion adsorption filter is preferably a filter which can perform ion exchange. Herein, the metal ions to be adsorbed are not particularly limited. However, a metal ion containing one kind of element selected from the group consisting of Fe, Cr, Ni, and Pb is preferable, and metal ions containing Fe, Cr, Ni, and Pb are preferable, because these readily become the cause of a defect in a semiconductor device.

From the viewpoint of improving the metal ion adsorption performance, it is preferable that the metal ion adsorption filter contains an acid group on the surface thereof Examples of the acid group include a sulfo group, a carboxy group, and the like.

Examples of the base material (material) constituting the metal ion adsorption filter include cellulose, diatomite, nylon, polyethylene, polypropylene, polystyrene, a fluororesin, and the like. From the viewpoint of the metal ion adsorption efficiency, nylon is particularly preferable.

The metal ion adsorption filter may be constituted with material including polyimide and/or polyamide imide. Examples of the metal ion adsorption filter include the polyimide and/or polyamide imide porous membrane described in JP2016-155121A.

The polyimide and/or polyamide imide porous membrane may contain at least one group selected from the group consisting of a carboxy group, a salt-type carboxy group, and a —NH— bond. In a case where the metal ion adsorption filter is formed of a fluororesin, polyimide, and/or polyamide imide, the filter has further improved solvent resistance.

### Organic Impurity Adsorption Filter

The filtering device may further have an organic impurity adsorption filter.

The organic impurity adsorption filter is not particularly limited, and examples thereof include known organic impurity adsorption filters.

In view of improving the organic impurity adsorption performance, it is preferable that the organic impurity adsorption filter has the skeleton of an organic substance, which can interact with the organic impurity, on the surface thereof (in other words, it is preferable that the surface of the organic impurity adsorption filter is modified with the skeleton of an organic substance which can interact with the organic impurity). Examples of the skeleton of an organic substance which can interact with the organic impurity include a chemical structure which can react with the organic impurity so as to make the organic impurity trapped in the organic impurity adsorption filter. More specifically, in a case where the chemical liquid contains long-chain n-alkyl alcohol (corresponding to a structural isomer in a case where the chemical liquid contains long-chain 1-alkyl alcohol) as the organic impurity, examples of the skeleton of an organic substance include an alkyl group. Furthermore, in a case where the chemical liquid contains dibutylhydroxytoluene (BHT) as the organic impurity, examples of the skeleton of an organic substance include a phenyl group.

Examples of the base material (material) constituting the organic impurity adsorption filter include cellulose supporting active carbon, diatomite, nylon, polyethylene, polypropylene, polystyrene, a fluororesin, and the like.

Furthermore, as the organic impurity adsorption filter, it is possible to use the filters obtained by fixing active carbon to non-woven cloth that are described in JP2002-273123A and JP2013-150979A.

For the organic impurity adsorption filter, in addition to the chemical adsorption described above (adsorption using the organic impurity adsorption filter having the skeleton of an organic substance, which can interact with the organic impurity, on the surface thereof), a physical adsorption method can be used.

For example, in a case where the organic impurity contains BHT, the structure of BHT is larger than 10 angstroms (=1 nm). Accordingly, in a case where an organic impurity adsorption filter having a pore size of 1 nm is used, BHT cannot pass through the pore of the filter. That is, by being physically trapped by the filter, BHT is removed from the substance to be purified. In this way, for removing an organic impurity, not only a chemical interaction but also a physical removing method can be used. Here, in this case, a filter having a pore size equal to or greater than 3 nm is used as “particle removing filter”, and a filter having a pore size less than 3 nm is used as “organic impurity adsorption filter”.

### Other Devices

The manufacturing device may comprise devices other than those described above. Examples of the devices that the manufacturing device may comprise include a reaction container, an ion exchange unit, and the like.

As the ion exchange unit, known ion exchange units can be used without particular limitation. Examples of the ion exchange unit include tower-like container storing an ion exchange resin, an ion adsorption membrane, and the like.

Examples of an aspect of the ion exchange step include a step in which a cation exchange resin or an anion exchange resin provided as a single bed is used as an ion exchange resin, a step in which a cation exchange resin and an anion exchange resin provided as a dual bed are used as an ion exchange resin, and a step in which a cation exchange resin and an anion exchange resin provided as a mixed bed are used as an ion exchange resin.

In order to reduce the amount of moisture eluted from the ion exchange resin, as the ion exchange resin, it is preferable to use a dry resin which does not contain moisture as far as possible. As the dry resin, commercial products can be used, and examples thereof include 15JS-HG·DRY (trade name, dry cation exchange resin, moisture: equal to or smaller than 2%) and MSPS2-1·DRY (trade name, mixed bed resin, moisture: equal to or smaller than 10%) manufactured by ORGANO CORPORATION, and the like.

It is preferable that the ion exchange unit is disposed in the supply pipe line 109 so as to be positioned between the tank 101 and the filtering device 105 or behind the tank 101 and the filtering device 105.

As the reaction container, known reaction containers can be used. The reaction container has a function of manufacturing an organic solvent to be incorporated into the chemical liquid. It is preferable that the reaction container is disposed in front of the distillation column 201 in the manufacturing device 200 shown in FIG. 2 and is connected to the distillation column 201 through the pipe line 203 such that a fluid can be transferred between the distillation column 201 and the reaction container through the pipe line 203.

### Setup Step

The chemical liquid manufacturing method according to the embodiment of the present invention has a setup step having a step A and a step B that will be described later, in which the step A and the step B are repeatedly performed until a washing solution extracted from the manufacturing device satisfies a condition 1 after the step A and the step B.

In the present specification, a step of checking whether the washing solution extracted from the manufacturing device satisfies the condition 1 is referred to as first checking step as well.

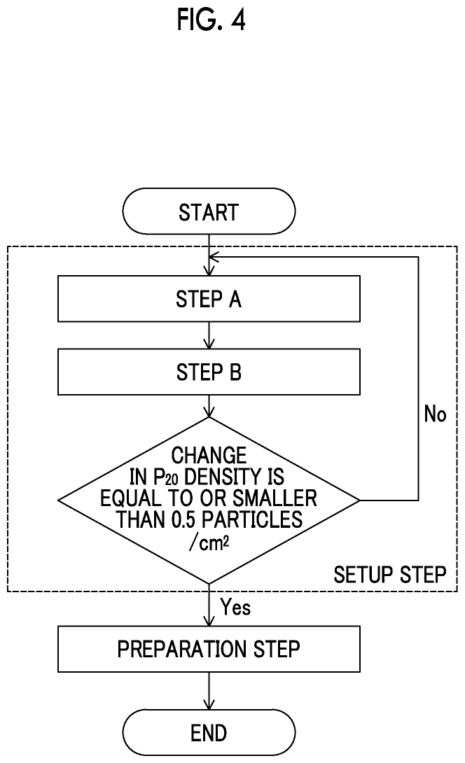

Hereinafter, the step A and the step B that the setup step has will be described first, and then the entirety of the setup step will be described using FIG. 4.

### Step A

The step A is a step of washing the manufacturing device by using a washing solution. In the step A, at least a portion of the manufacturing device may be washed. In a case where the manufacturing device comprises a tank, it is preferable that at least a liquid contact portion of the tank is washed.

As the washing method, known methods can be used without particular limitation. In the case of the manufacturing device comprising a tank illustrated in FIG. 1, for example, a method of supplying a washing solution into the manufacturing device from the supply port 102 of the tank 101 and washing the manufacturing device by transferring the washing solution through pipe lines is used. An example of the washing method will be specifically described using the manufacturing device 100 shown in FIG. 1.

First, a washing solution is supplied from the supply port 102 of the tank 101. The amount of the washing solution supplied is not particularly limited, but is preferably an amount enough for the liquid contact portion of the tank 101 to be thoroughly washed. The volume of the washing solution supplied is preferably equal to or greater than 30% by volume with respect to the volume of the tank 101. At the time of supplying the washing solution from the supply port 102, the valve 103 may be closed or opened. However, in view of more easily washing the tank 101, it is preferable that the valve 103 is closed at the time of supplying the washing solution from the supply port 102. The washing solution which can be used in the step A according to the embodiment of the present invention will be described later.

The washing solution supplied into the tank 101 may be directly transferred into the manufacturing device or transferred into the manufacturing device (for example, through the supply pipe line 109) after washing the interior of the tank 101. The method for washing the interior of the tank 101 by using the washing solution is not particularly limited, and examples thereof include a method of performing washing by rotating a stirring blade that the tank 101 comprises and is not shown in the drawing. The time for which the tank is washed using the washing solution is not particularly limited, and may be appropriately selected according to the material of the liquid contact portion of the tank 101, the type of the chemical liquid to be manufactured, the likelihood of contamination, and the like. Generally, the tank is washed for about 0.1 seconds to 48 hours. In a case where only the tank 101 is washed, the washing solution having been used for washing may be discharged from a discharge port not shown in the drawing that is provided at the bottom of the tank.

The method for washing the supply pipe line 109 or the like of the manufacturing device 100 by using the washing solution is not particularly limited, and is preferably a method of opening the valve 103 and the valve 106 while closing the valve 107 and then operating the pump 104 such that the washing solution circulates in the manufacturing device through the supply pipe line 109 and the circulation pipe line 110 (hereinafter, this method will be referred to as “circulation washing” as well). In a case where the above method is used, it is possible to more efficiently dispersing and/or dissolving foreign substances and the like having adhered to the liquid contact portion of the tank 101, the filtering device 105, the supply pipe line 109, and the like while transferring the washing solution.

In a case where the manufacturing device comprises a filtering device, as the washing method, circulation washing is more preferable. An example of circulation washing will be described using FIG. 1. The washing solution supplied into the manufacturing device from the tank 101 through the valve 103 flows (circulates) back to the tank 101 through the supply pipe line 109 (through the filtering device 105, the circulation pipe line 110, and the valve 106). At this time, the washing solution is filtered through the filtering device 105, and particles and the like dissolved and dispersed in the washing solution are removed. Accordingly, the washing effect can be further improved.

In other words, in a case where the step A and the step B, which will be described later, are repeatedly performed in the setup step, it is preferable that the washing solution having been used in the step A is filtered through the filtering device, and the filtered washing solution is used in the step A.

In the present specification, in a case where the manufacturing device comprising a tank is subjected to circulation washing, at point in time when the entirety of the washing solution supplied into the device from the tank 101 has returned to the tank 101, the number of times of the circulation washing is regarded as 1. The “entirety” means that the volume of the returning washing solution is equal to or greater than 90% by volume with respect to the volume of the supplied washing solution. The volume of the returning washing solution is more preferably equal to or greater than 95% by mass.

The number of times of the circulation washing is not particularly limited. Generally, the number of time of the circulation washing is preferably equal to or greater than 2, and more preferably equal to or greater than 3. The upper limit of the number of times of the circulation washing is not particularly limited. Generally, the upper limit is preferably equal to or smaller than 50, and more preferably equal to or smaller than 25. In a case where the number of time of the circulation washing is equal to or greater than 3, it is easy to obtain a chemical liquid having a further improved defect inhibition performance.

As another aspect of the washing method, for example, a method may be used in which the valve 103 and the valve 107 is opened while the valve 106 is closed, then the pump 104 is operated such that the washing solution supplied into the manufacturing device from the supply port 102 of the tank 101 flows into the filtering device 105 through the valve 103 and the pump 104, and then the washing solution is discharged out of the manufacturing device through the valve 107 without being circulated (hereinafter, in the present specification, this method will be referred to as “batch washing” as well). In this case, as described above, a certain amount of the washing solution may be intermittently or continuously supplied into the manufacturing device.

As another aspect of the step A, a case where the manufacturing device 200 comprising a distillation column will be described. First, the washing solution is supplied to the distillation column 201 from the pipe line 203. Then, the distillation column 201 is operated such that the washing solution is distilled. At this time, while the gasification and condensation of the washing solution are being repeated, the interior of the distillation column 201 is washed. The washing solution gasified in the distillation column is liquefied in a condenser not shown in the drawing, passed through the pipe line 202, and stored in the tank 101.

After the washing solution is stored in the tank 101, the liquid contact portion of the manufacturing device is washed by the method such as circulation washing and/or the batch washing described above. At the time of washing the manufacturing device, if necessary, the valve 103 and valves 205 to 207 may be switched with each other, such that the washing solution discharged from the tank 101 flows into the distillation column 201 through the pipe line 203 and the pipe line 204 and washes again the liquid contact portion of the distillation column 201.

Prior to the setup step, it is preferable that the liquid contact portion of the member relating to the manufacturing device (for example, the filter that the filtering device comprises, or the like) is washed. As a liquid used for washing, in addition to the washing solution which will be described later, an organic solvent with a small impurity content (for example, a high-grade product used for semiconductors or an organic solvent obtained by further purifying the high-grade product), the manufactured chemical liquid, or a liquid obtained by diluting the chemical liquid is preferable. In this case, it is preferable to perform washing until the liquid used for washing satisfies each of the conditions which will be described later.

### Washing Solution

As the washing solution, known washing solutions can be used without particular limitation.

Examples of the washing solution include water, alkylene glycol monoalkyl ether carboxylate, alkylene glycol monoalkyl ether, a lactic acid alkyl ester, alkoxyalkyl propionate, cyclic lactone (preferably having 4 to 10 carbon atoms), a monoketone compound which may have a ring (preferably having 4 to 10 carbon atoms), alkylene carbonate, alkoxyalkyl acetate, alkyl pyruvate, and the like.

Furthermore, as the washing solution, those described in JP2016-057614A, JP2014-219664A, JP2016-138219A, and JP2015-135379A may also be used.

The washing solution preferably contains at least one kind of compound selected from the group consisting of PGME, CyPe, CyPn, nBA, PGMEA, CyHe, EL, HBM, DBCPN, GBL, DMSO, EC, PC, NMP, iAA, IPA, MEK, and MIBC, more preferably contains at least one kind of compound selected from the group consisting of PGMEA, NMP, PGME, nBA, PC, CyHe, GBL, MIBC, EL, DMSO, iAA, MEK, and CyPe, and is even more preferably formed of at least one kind of compound selected from the group consisting of PGMEA, NMP, PGME, nBA, PC, CyHe, GBL, MIBC, EL, DMSO, iAA, MEK, and CyPe.

One kind of washing solution may be used singly, or two or more kinds of washing solutions may be used in combination.

Examples of the washing solution include, in addition to the above compounds, alcohols such as methanol, ethanol, propanol, butanol, methoxyethanol, butoxyethanol, methoxypropanol, and ethoxypropanol; a ketone-based washing solution such as acetone and methyl ethyl ketone; an ether-based washing solution such as tetrahydrofuran, dioxane, ethylene glycol dimethyl ether, and diethylene glycol dimethyl ether; an ester-based washing solution such as ethyl acetate and ethyl cellosolve acetate; aromatic compounds such as benzene, toluene, and xylene; chlorinated hydrocarbons such as dichloromethane, dichloroethane, dichloroethylene, and trichloroethylene; and the like.

In view of obtaining a chemical liquid having a further improved defect inhibition performance, it is preferable that the washing solution has a relationship with the organic solvent contained in the chemical liquid such that a difference in a contribution rate of Hansen solubility parameters (a difference between a contribution rate of Hansen solubility parameters of the washing solution and a contribution rate of Hansen solubility parameters of the organic solvent contained in the chemical liquid) becomes 0 to 30.

In the present specification, Hansen solubility parameters mean those described in “Hansen Solubility Parameters: A Users Handbook” (Second Edition, pp. 1-310, CRC Press, 2007), and the like. That is, Hansen solubility parameters describe solubility by using multi-dimensional vectors (a dispersion element (δd), a dipole-dipole force element (δp), and a hydrogen bond element (δh)). These three parameters can be considered as coordinates of points in a three-dimensional space called Hansen space. The unit of each of the elements of the Hansen solubility parameters is (MPa)^{0.5}.

In the present specification, a contribution rate (fd) of the dispersion element in Hansen solubility parameters, a contribution rate (fp) of the dipole-dipole force element in Hansen solubility parameters, and a contribution rate (fh) of the hydrogen bond element in Hansen solubility parameters can be calculated using Equations (1) to (3).

fd=δd/(δd+δp+δh)×100 (unit: %) Equation (1)

fp=δp/(δd+δp+δh)×100 (unit: %) Equation (2)

fh=δh/(δd+δp+δh)×100 (unit: %) Equation (3)

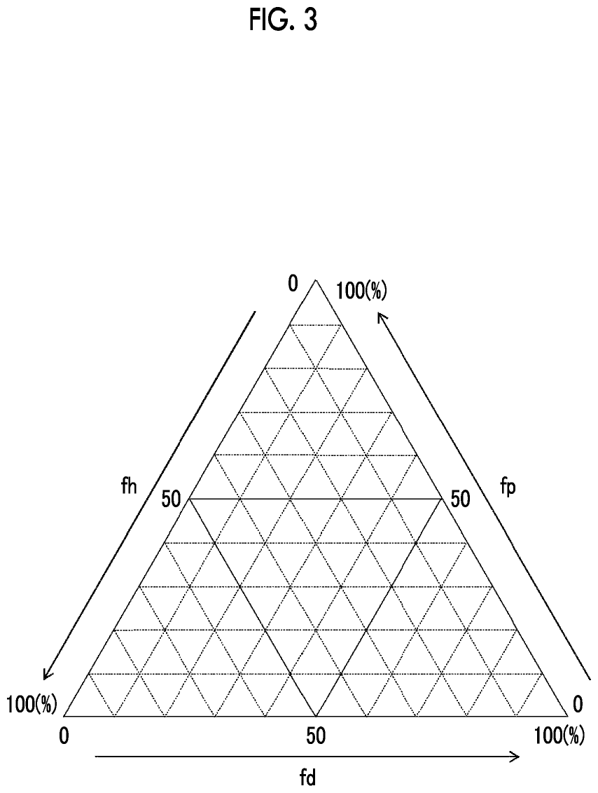

FIG. 3 is a ternary diagram with apexes each showing a contribution rate of the dispersion element in Hansen solubility parameters, a contribution rate of the dipole-dipole force element in Hansen solubility parameters, and a contribution rate of the hydrogen bond element in Hansen solubility parameters.

In the ternary diagram with apexes each showing a contribution rate of the dispersion element in Hansen solubility parameters, a contribution rate of the dipole-dipole force element in Hansen solubility parameters, and a contribution rate of the hydrogen bond element in Hansen solubility parameters, the position of each organic solvent is as below. In the present paragraph, the numbers described in the bracket following the name of the organic solvent represent (the contribution rate of the dispersion element: fd, the contribution rate of the dipole-dipole force element: fp, the contribution rate of the hydrogen bond element: fh) respectively.

nBA (60.6, 17.2, 22.2), NMP (48.0, 32.8, 19.2), EL (55.5, 19.8, 24.7), PGMEA (56.5, 19.8, 23.7), PGME (46.6, 32.1, 21.3), iAA (63.2, 15.8, 21.0), MIBC (51.5, 14.5, 34.0), IPA (43.0, 18.0, 39.0), CyHx (61.0, 21.6, 17.5), CyPn (62.0, 20.9, 17.1), CyHe (61, 21.5, 17.5), PC (42.9, 39.5, 17.6), DMSO (40.9, 36.4, 22.7), GBL (42.9, 39.5, 17.6), HBM (46.0, 20.0, 34.0), DBCPN (65.4, 18.1, 16.5).

Next, the difference in the contribution rate of Hansen solubility parameters will be described. The method for calculating the difference in the contribution rate is described in Hideki Yamamoto, “SP Value, Fundamentals·Application and Calculation method”, 2^{nd} printing, pp. 81-84, Mar. 31, 2005, JOHOKIKO CO., LTD.

For example, in the case of an organic solvent (fd₁, fp₁, fh₁) and a washing solution (fd₂, fp₂, fh₂), the difference in the contribution rate is calculated by the following equation.

(Difference in contribution rate)={(fd₁−fd₂)²+(fp₁−fp₂)²+(fh₁−fh₂)²}^{1/2}

The difference in the contribution rate represents a distance between an organic solvent and a washing solution plotted on the ternary diagram shown in FIG. 3.

### Step B

The step B is a step of extracting the washing solution from the manufacturing device. The method for extracting the washing solution is not particularly limited. For example, after the end of the step A, the washing solution may be drawn from the washing solution monitoring portion 112 (in the case of circulation washing) or from the pipe line 113 of the discharge portion 111 (in the case of batch washing). A portion of the washing solution may be drawn, or the entirety of the washing solution may be drawn. In a case where a portion of the washing solution is drawn, the washing solution remaining in the manufacturing device can be used in a new step A at the time of circulation washing.

FIG. 4 is a flowchart showing a chemical liquid manufacturing method according to an embodiment of the present invention having a first checking step. In a case where the manufacturing of a chemical liquid is started, the step A and the step B described above are performed in this order, and from the manufacturing device, a portion of the washing solution having been used for washing the manufacturing device or the entirety of the washing solution having been used for washing the manufacturing device is extracted. In the setup step, the step A and the step B are repeated until the washing solution extracted from the manufacturing device satisfies the following condition 1 after the step A and the step B.

### Condition 1

According to the condition 1, in a case where a substrate is coated with the washing solution, a change in density of particles, which have a particle diameter equal to or smaller than 20 nm (hereinafter, the density will be referred to as “P₂₀ density” as well), on the substrate before and after the coating with the washing solution is equal to or smaller than 0.5 particles/cm². In view of obtaining a chemical liquid having a further improved defect inhibition performance, the P₂₀ density in the condition 1 is more preferably equal to or lower than 0.01 particles/cm².

According to the chemical liquid manufacturing method having the above step, a chemical liquid having an excellent defect inhibition performance can be obtained.

The method for checking whether the washing solution extracted from the manufacturing device satisfies the condition 1 will be described. First, a substrate is coated with the washing solution. The substrate used at this time is not particularly limited, but is preferably a silicon wafer because this substrate makes it possible to more simply measure the change in the P₂₀ density. As the coating method, spin coating is preferable.

Then, the change in the P₂₀ density on the substrate before and after the coating is measured, and whether the change is equal to or smaller than 0.5 particles/cm² is checked.

By measuring the P₂₀ density on the substrate not yet being coated with the washing solution and the P₂₀ density on the substrate having been coated with the washing solution and calculating a difference therebetween, the change in the P₂₀ density on the substrate before and after the coating with the washing solution can be calculated. In this case, for measuring the P₂₀ density on the substrate before and after the coating, it is possible to use a method generally used for measuring the number of defects on a substrate. For example, it is possible to use the measurement of the number of defects by using a defect inspection device such as SP-5 manufactured by KLA-Tencor Corporation.

In the chemical liquid manufacturing method shown in FIG. 4, first, the step A is performed such that the manufacturing device is washed using the washing solution. Then, the step B is performed such that the washing solution is extracted from the manufacturing device. Thereafter, the P₂₀ density on the substrate before and after the coating with the washing solution is measured. At this time, in a case where the change in the P₂₀ density is found to be equal to or smaller than 0.5 particles/cm², the washing solution is fully discharged from the manufacturing device as necessary, and the preparation step, which will be described later, is performed.

In contrast, in a case where the change in the P₂₀ density is higher than 0.5 particles/cm², the manufacturing device is washed again (a new step A is performed). At this time, in a case where a portion of the washing solution is extracted from the manufacturing device in the step B described above, and hence the washing solution remains in the manufacturing device (for example, in the tank), the manufacturing device may be washed again by using the remaining washing solution (a new step A may be performed). In this case, as described above, the washing solution in the manufacturing device may be filtered using the filtering device so as to perform circulation washing. Furthermore, at this time, a new washing solution may be added. Meanwhile, the entirety of the washing solution may be discharged in the step B described above, and the manufacturing device may be washed again in the new step A by using only the new washing solution. After the washing (after the end of the new step A), the washing solution is extracted again (new step B), and the P₂₀ density is measured (remeasurement). In a case where the change is found to be equal to or smaller than 0.5 particles/cm² by the remeasurement, the washing solution is fully discharged from the interior of the manufacturing device as necessary, and the preparation step, which will be described later, is performed.

In a case where the change is found to be higher than 0.5 particles/cm² by the remeasurement, the manufacturing device is washed again (the step A is performed), the washing solution is then extracted (the step B is performed), and the above operation is repeated until the change in the P₂₀ density is found to be equal to or smaller than 0.5 particles/cm².

### Additional Condition 2

In view of obtaining a chemical liquid having a further improved defect inhibition performance, the setup step is preferably a step of repeatedly performing the step A and the step B until the washing solution extracted from the manufacturing device further satisfies the following additional condition 2.

In the present specification, a step of checking whether the washing solution extracted from the manufacturing device satisfies the additional condition 2 is referred to as second checking step as well.

Additional condition 2: in a case where a substrate is coated with the washing solution, a change in density of particles, which have a particle diameter greater than 20 nm and equal to or smaller than 100 nm (hereinafter, the particles will be referred to as “P₁₀₀” as well), on the substrate before and after the coating with the washing solution is equal to or smaller than 0.04 particles/cm².

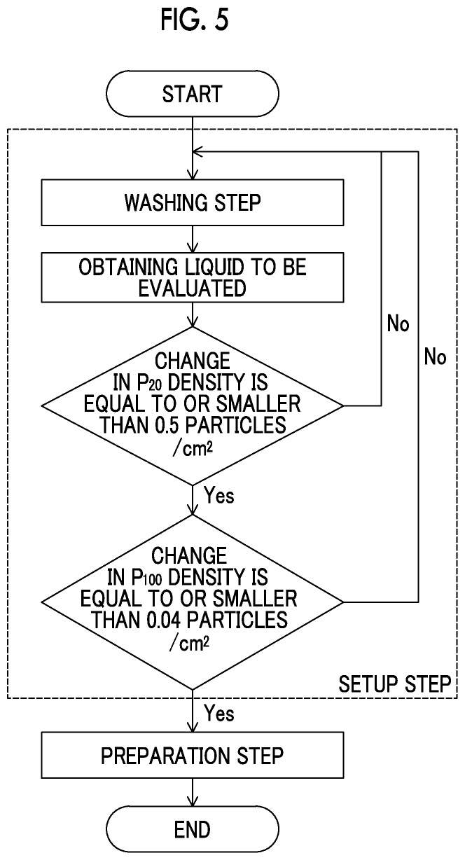

FIG. 5 is a flowchart showing the chemical liquid manufacturing method according to an embodiment of the present invention having a second checking step in which in the setup step, the step A and the step B are repeated until the washing solution further satisfies the additional condition 2.

In the chemical liquid manufacturing method described in FIG. 5, in a case where the manufacturing of a chemical liquid is started, the step A is performed such that the manufacturing device is washed. Then, the step B is performed such that the washing solution is extracted from the manufacturing device. Thereafter, the change in the P₂₀ density on the substrate before and after the coating with the washing solution is measured. The method for extracting the washing solution from the manufacturing device and the method for measuring the change in the P₂₀ density are as described above.

At this time, in a case where the change is found to be equal to or smaller than 0.5 particles/cm², the change in the P₁₀₀ density on the substrate before and after the coating with the washing solution is then measured. At this time, in a case where the change is found to be equal to or smaller than 0.04 particles/cm², the washing solution is fully discharged out of the manufacturing device as necessary, and the preparation step, which will be described later, is performed.

In FIG. 5, the change in the P₂₀ density on the substrate is measured, and then the change in the P₁₀₀ density on the substrate is measured. However, the change in the P₂₀ density and the change in the P₁₀₀ density may be measured in a reverse order or measured simultaneously.

In a case where the measurement result is greater than a predetermined value, the manufacturing device is washed again (the step A is performed), the washing solution is extracted from the manufacturing device after the washing ends (the step B is performed), and the step A and the step B are repeated for the extracted washing solution until the change in the P₂₀ density and the change in the P₁₀₀ density on the substrate are found to be equal to or smaller than 0.5 particles/cm² and equal to or smaller than 0.04 particles/cm² respectively.

In a case where the change in the P₂₀ density and the change in the P₁₀₀ density are found to be within a predetermined range, the washing solution is fully discharged out of the manufacturing device as necessary, and the preparation step, which will be described later, is performed.

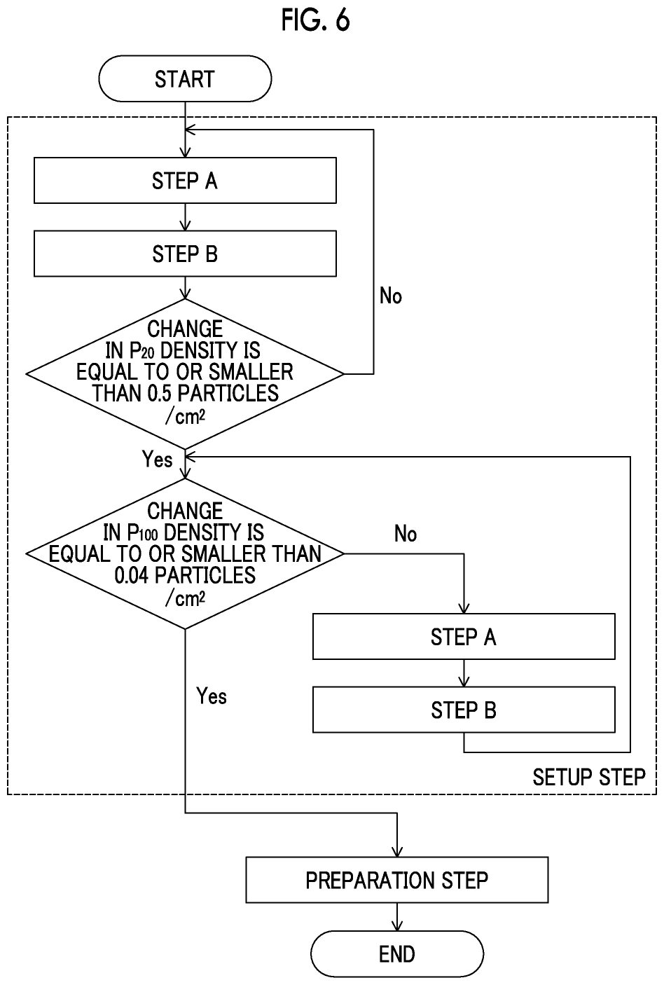

FIG. 6 is a flowchart showing another aspect of the chemical liquid manufacturing method according to the embodiment of the present invention having the second checking step. In the chemical liquid manufacturing method shown in FIG. 6, first, the step A is performed such that the manufacturing device is washed. Then, after the washing ends, the step B is performed such that the washing solution is extracted from the manufacturing device. Thereafter, for the extracted washing solution, the change in the P₂₀ density on the substrate before and after the coating with the washing solution is measured. At this time, in a case where the change is greater than 0.5 particles/cm², the step A is performed again, and the step A and the step B are repeated until the change in the P₂₀ density becomes equal to or smaller than 0.5 particles/cm^{2.}

In contrast, in a case where the change in the P₂₀ density of the washing solution is 0.5 particles/cm², the second checking step is then performed. Thereafter, in a case where the change in the P₁₀₀ density is measured using the washing solution extracted from the manufacturing device, and the change is found to be greater than 0.04 particles/cm², the manufacturing device is washed again, the washing solution is extracted from the manufacturing device, and the change in the P₁₀₀ density is measured. At this time, in a case where the change in the P₂₀ density of the washing solution is 0.5 particles/cm², the change in the P₂₀ density is not measured again.

In FIG. 6, the change in the P₂₀ density is measured, and then the change in the P₁₀₀ density is measured. However, the change in the P₂₀ density and the change in the P₁₀₀ density may be measured in the reverse order or measured simultaneously. According to the chemical liquid manufacturing method of the embodiment described above, a chemical liquid can be more efficiently manufactured.

### Additional Condition 3

In view of obtaining a chemical liquid having a further improved defect inhibition performance, the setup step is preferably a step of repeatedly performing the step A and the step B until the washing solution extracted from the manufacturing device further satisfies the following additional condition 3.

In the present specification, a step of checking whether the washing solution extracted from the manufacturing device satisfies the additional condition 3 will be referred to as third checking step as well.

Additional condition 3: in the washing solution, a content of each of impurity metals containing each of Fe, Cr, Pb, and Ni (hereinafter, the impurity metal will be referred to as “specific impurity metals” as well) is 0.001 to 10 mass ppt. In other words, the content of each of the impurity metal containing Fe, the impurity metal containing Cr, the impurity metal containing Ni, and the impurity metal containing Pb is 0.001 to 10 mass ppt.

In the additional condition 3, in view of easily obtaining a chemical liquid having a further improved defect inhibition performance, the content of the specific impurity metal is more preferably equal to or greater than 0.001 mass ppt and less than 0.1 mass ppt. Presumably, particularly in a case where the content of each of the specific impurity metals is equal to or greater than 0.001 mass ppt, the chemical liquid may contain a trace of the specific impurity metals, the specific impurity metals in the chemical liquid may be easily aggregated with each other, and accordingly, the chemical liquid may have a further improved defect inhibition performance.

The state of the specific impurity metals in the chemical liquid is not particularly limited. In the present specification, the specific impurity metals mean metal components which can be measured using a single particle inductively coupled plasma emission mass spectrometer and contain each of Fe, Cr, Pb, and Ni in the washing solution. With the aforementioned device, it is possible to measure the content and the total content of a particle-like impurity metal and an impurity metal other than that (for example, ions and the like). In the present specification, “the content of the specific impurity metals” simply means the total content. The washing solution may contain both the particle-like specific impurity metal and specific impurity metal other than that (for example, ions and the like).

In the present specification, the specific impurity metals can be measured by the method described in Examples by using Agilent 8800 triple quadrupole inductively coupled plasma mass spectrometry manufactured by Agilent Technologies, Inc (ICP-MS, for semiconductor analysis, option #200) (or Agilent 8900 manufactured by Agilent Technologies, Inc).

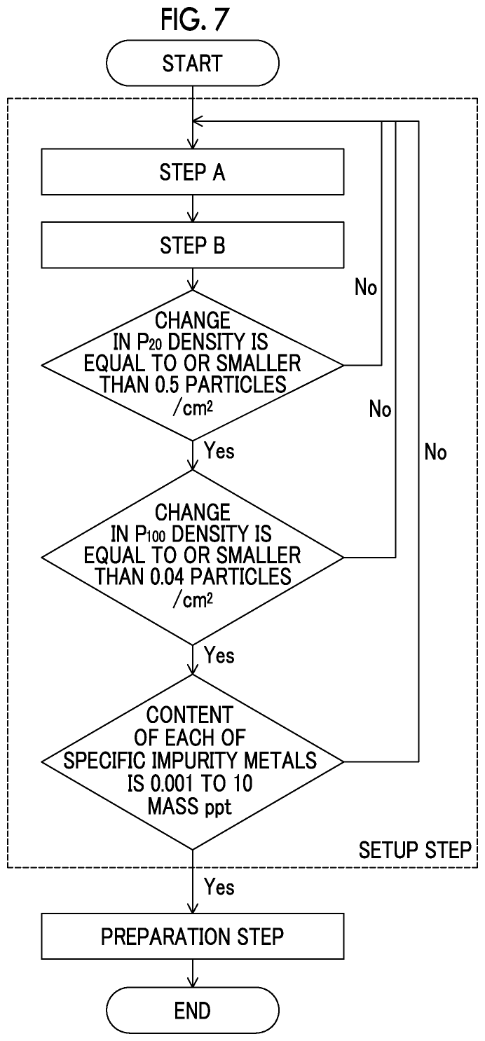

FIG. 7 is a flowchart showing the chemical liquid manufacturing method according to the embodiment of the present invention having a third checking step.

In FIG. 7, in a case where the manufacturing of a chemical liquid is started, the step A is performed, and after washing ends, the step B is performed such that the washing solution is extracted from the manufacturing device. For the washing solution, the change in the P₂₀ density on the substrate before and after the coating with the washing solution is measured. At this time, in a case where the change is found to be equal to or smaller than 0.5 particles/cm², the change in the P₁₀₀ density on the substrate before and after the coating with the washing solution is then measured. At this time, in a case where the change is found to be equal to or smaller than 0.04 particles/cm², the content of the specific impurity metals in the washing solution is measured. At this time, in a case where the content of each of the specific impurity metals is found to be 0.001 to 10 mass ppt, the washing solution is discharged from the manufacturing device as necessary, and the preparation step, which will be described later, is performed.

In FIG. 7, the change in the P₂₀ density on the substrate is measured, the change in the P₁₀₀ density on the substrate is then measured, and then the content of the specific impurity metals is measured. However, the order of measurement is not limited. The change in the P₂₀ density, the change in the P₁₀₀ density, and the content of the specific impurity metals may be measured in a reverse order or measured simultaneously.

The setup step in the chemical liquid manufacturing method according to the embodiment of the present invention may not have the second checking step. That is, whether the washing solution satisfies the additional condition 2 may not be checked.

In a case where the measurement result is greater than a predetermined value, the manufacturing device is washed again, and the step A and the step B are repeated until the change in the P₂₀ density and the change in the P₁₀₀ density on the substrate are found to be equal to or smaller than 0.5 particles/cm² and equal to or smaller than 0.04 particles/cm² respectively, and the content of each of the specific impurity metals in the washing solution is found to be 0.001 to 10 mass ppt.

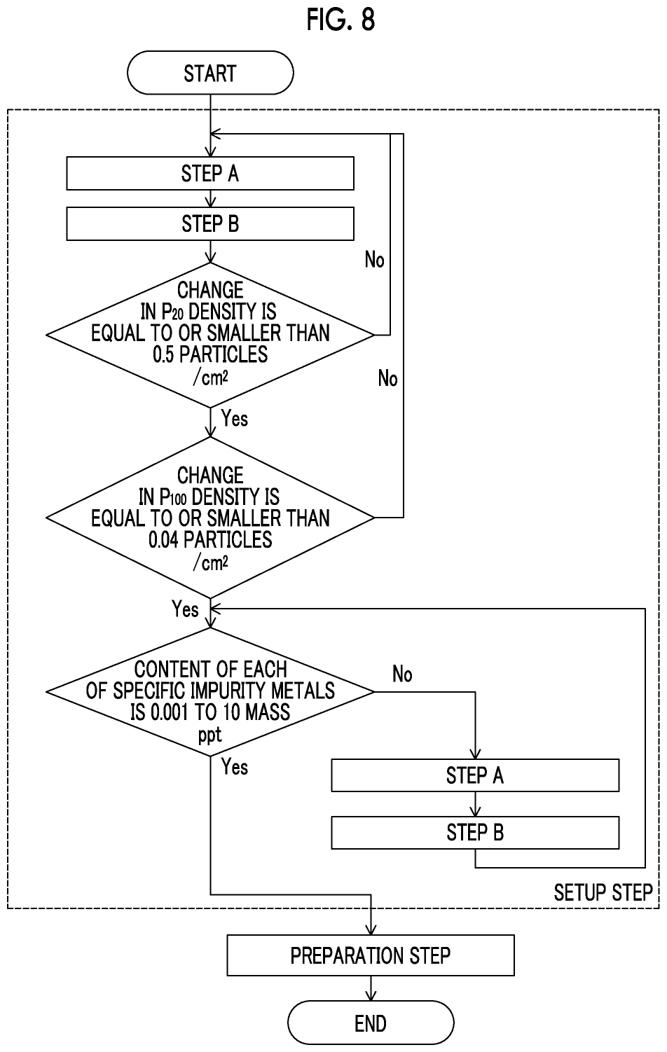

FIG. 8 is a flowchart showing the chemical liquid manufacturing method according to another embodiment of the present invention having the third checking step. In the chemical liquid manufacturing method described in FIG. 8, first, the step A is performed such that the manufacturing device is washed. Then, after the washing ends, the step B is performed such that the washing solution is extracted from the manufacturing device. Thereafter, for the washing solution, the change in the P₂₀ density on the substrate before and after the coating with the washing solution is measured, and then the change in the P₁₀₀ density is measured. At this time, the changes in the P₂₀ density and in the P₁₀₀ density may be measured simultaneously. In a case where the change in the P₂₀ density is greater than 0.5 particles/cm² or the change in the P₁₀₀ density is greater than 0.04 particles/cm², the washing step is performed again, and the step A and the step B are repeated until the change in the P₂₀ density and the change in the P₁₀₀ density become equal to or smaller than 0.5 particles/cm² and equal to or smaller than 0.04 particles/cm² respectively.

In a case where the change in the P₂₀ density and the change in the P₁₀₀ density are measured using the washing solution, and the changes are found to be in a predetermined range, the content of the specific impurity metals in the washing solution is then measured. The method for measuring the content of the specific impurity metals in the washing solution is as described above. At this time, in a case where the content of the specific impurity metals in the washing solution is outside a predetermined range, the step A and the step B are repeated again. Here, at this time, the changes in the P₂₀ density and in the P₁₀₀ density may not be measured again. That is, in a case where the content of the specific impurity metals in the washing solution is measured and found to be outside the range of 0.001 to 10 mass ppt, washing may be performed again, the washing solution may be extracted, and only the content of the specific impurity metals may be measured. In FIG. 8, the P₂₀ density and the P₁₀₀ density are measured, and then the specific impurity metals are measured. However, the P₂₀ density and the P₁₀₀ density and the specific impurity metals may be measured in the reverse order.

According to the chemical liquid manufacturing method of the embodiment described above, a chemical liquid can be more efficiently manufactured, and the content of the impurity metals in the obtained chemical liquid is easily further reduced. Accordingly, the chemical liquid has a further improved defect inhibition performance.

### Additional Condition 4

In view of obtaining a chemical liquid having a further improved defect inhibition performance, the setup step is preferably a step of repeatedly performing the step A and the step B until the washing solution extracted from the manufacturing device further satisfies the following additional condition 4.

In the present specification, a step of checking whether the washing solution extracted from the manufacturing device satisfies the additional condition 4 is referred to as fourth checking step as well.

Additional condition 4: in the washing solution, a content of an organic impurity having a boiling point equal to or higher than 250° C. is 0.001 to 10 mass ppm.

In the additional condition 4, in view of easily obtaining a chemical liquid having a further improved defect inhibition performance, the content of the organic impurity having a boiling point equal to or higher than 250° C. in the chemical liquid is more preferably equal to or greater than 0.001 mass ppm and less than 0.08 mass ppm. In a case where the content of organic impurity in the washing solution is 0.001 to 10 mass ppm, a chemical liquid having a further improved defect inhibition performance is easily obtained. Presumably, particularly in a case where the content of organic impurities is equal to or greater than 0.001 mass ppm, the chemical liquid may contain a trace of the organic impurities, the organic impurities in the chemical liquid may be easily aggregated with each other, and accordingly, the chemical liquid may have a further improved defect inhibition performance.

### Organic Impurity having Boiling Point Equal to or Higher than 250° C.

The organic impurity having a boiling point equal to or higher than 250° C. is not particularly limited, and examples thereof include known organic impurities having a boiling point equal to or higher than 250° C. Examples of the organic impurity include compounds represented by Formulae I to V.

In the present specification, the organic impurity means an organic compound which is different from the organic solvent contained in the chemical liquid and is contained in the chemical liquid in an amount equal to or smaller than 10,000 mass ppm with respect to the total mass of the chemical liquid. That is, in the present specification, an organic compound which is contained in the chemical liquid in an amount equal to or smaller than 10,000 mass ppm with respect to the total mass of the chemical liquid corresponds to an organic impurity but does not correspond to an organic solvent.

In a case where the chemical liquid contains a plurality of kinds of organic compounds, and each of the organic compounds is contained in the chemical liquid in an amount equal to or smaller than 10,000 mass ppm as described above, each of the organic compounds corresponds to the organic impurity.

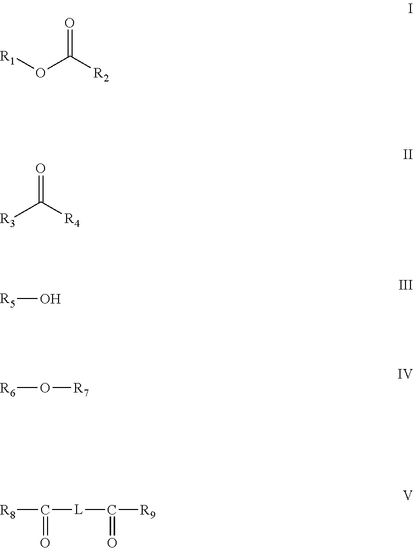

In Formula I, R₁ and R₂ each independently represent an amino group, an aryl group, an alkyl group, or a cycloalkyl group. Alternatively, R₁ and R₂ form a ring by being bonded to each other.

In a case where each of R₁ and R₂ represents a group other than an amino group, the number of carbon atoms in each of R₁ and R₂ is not particularly limited. Generally, the number of carbon atoms is 1 to 20 in many cases.

In Formula II, R₃ and R₄ each independently represent a hydrogen atom, an amino group, an aryl group, an alkyl group, an alkenyl group, a cycloalkyl group, or a cycloalkenyl group. Alternatively, R₃ and R₄ form a ring by being bonded to each other. Here, R₃ and R₄ do not simultaneously represent a hydrogen atom.

In a case where each of R₃ and R₄ represents a group other than an amino group, the number of carbon atoms in each of R₃ and R₄ is not particularly limited. Generally, the number of carbon atoms is 1 to 20 in many cases.

In Formula III, R₅ represents an alkyl group, an aryl group, or a cycloalkyl group. Generally, the number of carbon atoms in R₅ is 1 to 20 in many cases.

In Formula IV, R₆ and R₇ each independently represent an alkyl group, an aryl group, or a cycloalkyl group. Alternatively, R₆ and R₇ form a ring by being bonded to each other. The number of carbon atoms in each of R₆ and R₇ is not particularly limited. Generally, the number of carbon atoms is 1 to 20 in many cases.

In Formula V, R₈ and R₉ each independently represent an alkyl group, an aryl group, an alkyloxy group, or a cycloalkyl group. Alternatively, R₈ and R₉ form a ring by being bonded to each other. L represents a single bond or a divalent linking group.

The number of carbon atoms in each of R₈ and R₉ is not particularly limited. Generally, the number of carbon atoms is 1 to 20 in many cases.

Examples of the organic impurity also include a compound represented by Formula VI.

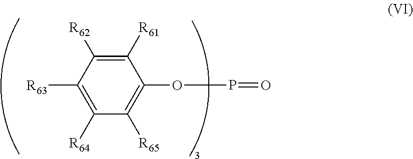

In Formula VI, R₆₁ to R₆₅ each independently represent an alkyl group. The number of carbon atoms in each of R₆₁ to R₆₅ is not particularly limited. Generally, the number of carbon atoms is 1 to 10 in many cases.

In view of obtaining a chemical liquid having a further improved defect inhibition performance, the fourth checking step is more preferably a step of checking whether the content of the organic impurity containing at least one kind of compound selected from the group consisting of Formulae (1) to (7) is 0.001 to 10 mass ppm in the washing solution. The content means the total content of the organic impurity. That is, the fourth checking step is a step of checking whether the total content of organic impurities is 0.001 to 10 mass ppm even though the washing solution contains the compound represented by Formula (1) and the compound represented by Formula (2) as organic impurities.

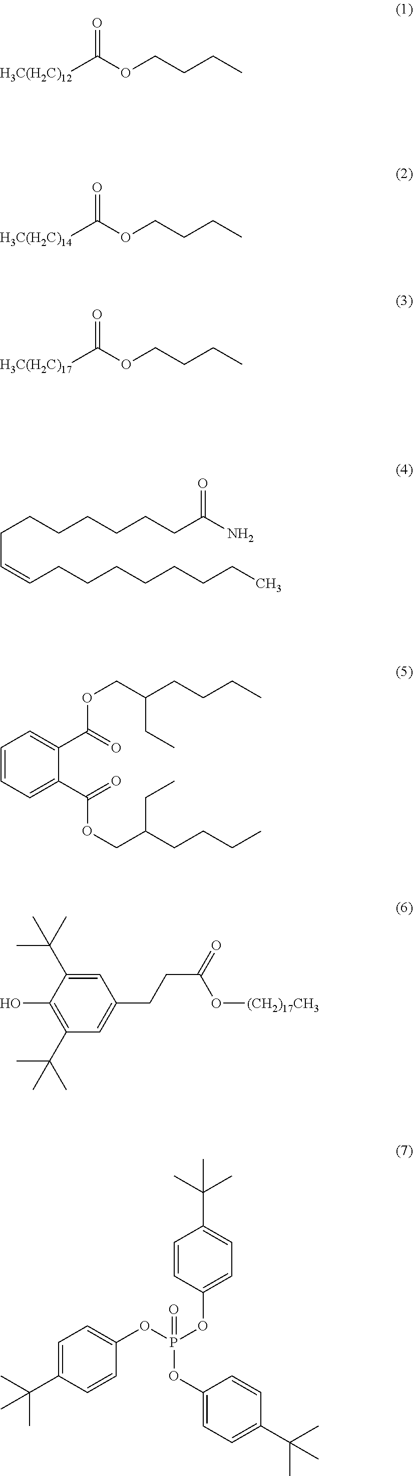

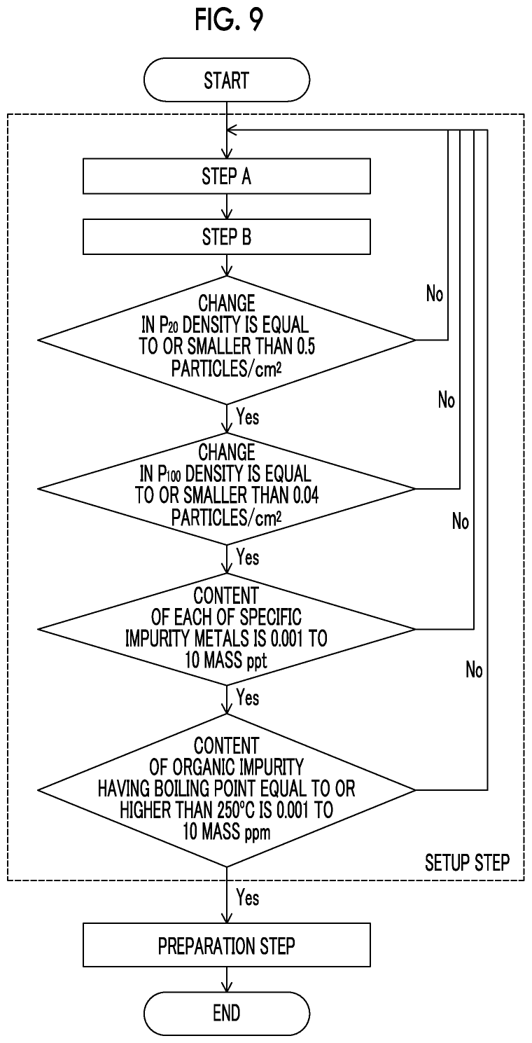

FIG. 9 is a flowchart showing the chemical liquid manufacturing method according to the embodiment of the present invention having the fourth checking step.

In the chemical liquid manufacturing method shown in FIG. 9, in a case where the manufacturing of a chemical liquid is started, the step A is performed such that the manufacturing device is washed. After the washing ends, the step B is performed such that the washing solution is extracted from the manufacturing device. Thereafter, for the washing solution, the change in the P₂₀ density on the substrate before and after the coating with the washing solution is measured. At this time, in a case where the change is found to be equal to or smaller than 0.5 particles/cm², the change in the P₁₀₀ density on the substrate before and after the coating with the washing solution is then measured. At this time, in a case where the change is found to be equal to or smaller than 0.04 particles/cm², the content of the specific impurity metals in the washing solution is measured. In a case where the content of each of the specific impurity metals is found to be 0.001 to 10 mass ppt, the content of the organic impurity in the washing solution is measured. At this time, particularly, the content of the organic impurity having a boiling point equal to or higher than 250° C. is measured. Subsequently, in a case where the content of the organic impurity having a boiling point equal to or higher than 250° C. in the washing solution is found to be 0.001 to 10 mass ppm, the washing solution is fully discharged out of the manufacturing device as necessary, and the preparation step, which will be described later, is performed.

In FIG. 9, the change in the P₂₀ density is measured first, the change in the P₁₀₀ density is then measured, the content of the specific impurity metals is then measured, and then the content of the organic impurity having a boiling point equal to or higher than 250° C. is measured. However, the order of measurement is not particularly limited. The change in the P₂₀ density, the change in the P₁₀₀ density, the content of the specific impurity metals, and the content of the organic impurity may be measured in a reverse order or measured simultaneously.

The setup step in the chemical liquid manufacturing method according to the embodiment of the present invention may not have the second checking step and/or the third checking step. That is, whether the washing solution satisfies the additional condition 2 and the additional condition 3 may not be checked.

In a case where the measurement result of the content of the organic impurity having a boiling point equal to or higher than 250° C. is greater than a predetermined value, the manufacturing device is washed again, and the step A and the step B are repeated until the change in the P₂₀ density is found to be equal to or smaller than 0.5 particles/cm², the change in the P₁₀₀ density is found to be equal to or smaller than 0.04 particles/cm², the content of each of the specific impurity metals is found to be 0.001 to 10 mass ppt, and the content of the organic impurity having a boiling point equal to or higher than 250° C. is found to be 0.001 to 10 mass ppm.

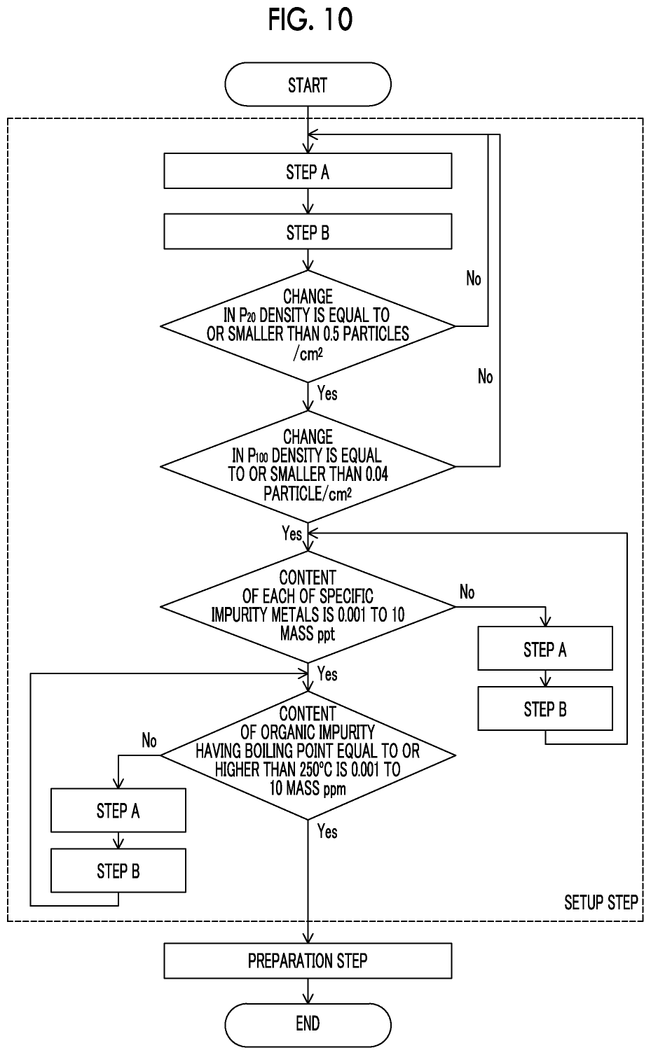

FIG. 10 is a flowchart showing the chemical liquid manufacturing method according to another embodiment of the present invention having the fourth checking step.

Until the third checking step, the chemical liquid manufacturing method described in FIG. 10 is performed according to the same aspect as described above as the chemical liquid manufacturing method shown in FIG. 8.

In the third checking step, in a case where the content of the specific impurity metals in the washing solution is found to be within a predetermined range, the content of the organic impurity having a boiling point equal to or higher than 250° C. in the washing solution is then measured. The method for measuring the content of the organic impurity having a boiling point equal to or higher than 250° C. in the washing solution is as described above. At this time, in a case where the content of the organic impurity having a boiling point equal to or higher than 250° C. in the washing solution is outside a predetermined range, the step A and the step B are repeated again. Here, the P₂₀ density, the P₁₀₀ density, and the content of the specific impurity metals may not be measured. That is, in a case where the measured content of the organic impurity having a boiling point equal to or higher than 250° C. in the washing solution is found to be outside a predetermined range, washing may be performed again, the washing solution may be obtained, and only the content of the organic impurity having a boiling point equal to or higher than 250° C. may be measured. In FIG. 10, the P₂₀ density, the P₁₀₀ density, and the content of the specific impurity metals are measured, and then the organic impurity having a boiling point equal to or higher than 250° C. is measured. However, the P₂₀ density, the P₁₀₀ density, the content of the specific impurity metals, and the organic impurity may be measured in a reverse order.

According to the chemical liquid manufacturing method of the embodiment, a chemical liquid can be more efficiently manufactured.

### Other Additional Conditions

In the setup step of the chemical liquid manufacturing method according to the present embodiment, the step A and the step B may be repeatedly performed until additional conditions other than the above are satisfied.

Examples of those other additional conditions include the following additional condition 5, but those other conditions are not limited thereto.

Additional condition 5: the number of particles having a particle diameter greater than 100 nm (hereinafter, referred to as “number of coarse particles” as well) in the washing solution is equal to or smaller than 5/mL.

In the present specification, the number of coarse particles represents the number of objects to be counted, which are counted by a light scattering-type liquid-borne particle counter, per unit volume (mL). The particles are counted under the following conditions.

.By using a light scattering-type liquid-borne particle counter (manufactured by RION Co., Ltd., model number: KS-18F, light source: semiconductor laser-excited solid-state laser (wavelength: 532 nm, rated power: 500 mW), flow rate: 10 mL/min, the measurement principle is based on a dynamic light scattering method), the number of particles having a size equal to or greater than 100 nm contained in 1 mL of the washing solution is counted 5 times, and the average thereof is adopted as the number of coarse particles.

The light scattering-type liquid-borne particle counter is used for measurement after being calibrated using a Polystyrene Latex (PSL) standard particle solution.

### Preparation Step

The preparation step is a step of preparing a chemical liquid by using the washed manufacturing device.

Typically, examples of the preparation step include a step of introducing an organic solvent as a raw material into the manufacturing device and mixing the organic solvent with other components as necessary. Particularly, in view of obtaining a chemical liquid having a further improved defect inhibition performance, it is preferable that the preparation step further has a step of filtering (filtering step) the organic solvent by using a manufacturing device comprising a tank and a filtering device which is connected to the tank through a pipe line and disposed such that a fluid can move between the tank and the filtering device through the pipe line.

### Filtering Step

It is preferable that the preparation step has a filtering step.

As a filter used in the filtering step, known filters can be used without particular limitation.

Examples of the material of the filter used in the filtering step include a fluororesin such as polytetrafluoroethylene (PTFE), a polyamide-based resin such as nylon, a polyolefin resin (including a polyolefin resin with high density and ultra-high molecular weight) such as polyethylene (PE) and polypropylene (PP), and the like. Among these, a polyamide-based resin, PTFE, and polypropylene (including high-density polypropylene) are preferable. In a case where filters formed of these materials are used, foreign substances with high polarity, which readily become the cause of a particle defect, can be more effectively removed, and the content of the metal component (impurity metal) can be efficiently reduced.

The lower limit of the critical surface tension of the filter is preferably equal to or higher than 70 mN/m. The upper limit thereof is preferably equal to or lower than 95 mN/m. The critical surface tension of the filter is more preferably equal to or higher than 75 mN/m and equal to or lower than 85 mN/m.

The value of the critical surface tension is the nominal value from manufacturers. In a case where a filter having critical surface tension within the above range is used, foreign substances with high polarity, which readily become the cause of a particle defect, can be effectively removed, and the amount of the metal component (metal impurity) can be efficiently reduced.

The pore size of the filter is preferably about 0.001 to 1.0 μm, more preferably about 0.01 to 0.5 μm, and even more preferably about 0.01 to 0.1 μm. In a case where the pore size of the filter is within the above range, it is possible to inhibit the clogging of the filter and to reliably remove minute foreign substances contained in the substance to be purified.

At the time of using the filter, different filters may be combined. At this time, filtering carried out using a first filter may be performed once or performed two or more times. In a case where filtering is performed two or more times by using different filters in combination, the filters may be of the same type or different types, but it is preferable that the filters are of different types. Typically, it is preferable that at least one of the pore size or the constituent material varies between the first filter and the second filter.

It is preferable that the pore size for the second filtering and the next filtering is the same as or smaller than the pore size for the first filtering. Furthermore, first filters having different pore sizes within the above range may be combined. As the pore size mentioned herein, the nominal values form filter manufacturers can be referred to. A commercial filter can be selected from various filters provided from, for example, Pall Corporation Japan, Advantec Toyo Kaisha, Ltd., Nihon Entegris KK (former MICRONICS JAPAN CO., LTD.), KITZ MICRO FILTER CORPORATION, or the like. In addition, it is possible to use “P-NYLON FILTER (pore size: 0.02 μm, critical surface tension: 77 mN/m)” made of polyamide; (manufactured by Pall Corporation Japan), “PE·CLEAN FILTER (pore size: 0.02 μm)” made of high-density polyethylene; (manufactured by Pall Corporation Japan), and “PE·CLEAN FILTER (pore size: 0.01 μm)” made of high-density polyethylene; (manufactured by Pall Corporation Japan).

For example, from the viewpoint of allowing the chemical liquid to bring about desired effects and from the viewpoint of inhibiting the increase of the impurity metal (particularly, a particle-like impurity metal) during the storage of the purified chemical liquid, provided that an interaction radius in the Hansen solubility parameter space derived from the material of the filter used for filtering is RO, and that a radius of a sphere in the Hansen space derived from the organic solvent contained in the substance to be purified is Ra, it is preferable that the substance to be purified and the material of the filter used for filtering are combined such that the substance to be purified and the filter have a relationship satisfying a relational expression of (Ra/R0)≤1, and the substance to be purified is preferably filtered through a filter material satisfying the relational expression. (Ra/R0) is preferably equal to or smaller than 0.98, and more preferably equal to or smaller than 0.95. The lower limit of (Ra/R0) is preferably equal to or greater than 0.5, more preferably equal to or greater than 0.6, and even more preferably 0.7. In a case where Ra/R0 is within the above range, the increase in the content of the impurity metal in the chemical liquid during long-term storage is inhibited, although the mechanism is unclear.

The combination of the filter and the substance to be purified is not particularly limited, and examples thereof include those described in US2016/0089622.

As a second filter, a filter formed of the same material as the aforementioned first filter can be used. Furthermore, a filter having the same pore size as the aforementioned first filter can be used. In a case where a filter having a pore size smaller than that of the first filter is used as the second filter, a ratio between the pore size of the second filter and the pore size of the first filter (pore size of second filter/pore size of first filter) is preferably 0.01 to 0.99, more preferably 0.1 to 0.9, and even more preferably 0.2 to 0.9. In a case where the pore size of the second filter is within the above range, fine foreign substances mixed into the substance to be purified are more reliably removed.

The filtering pressure affects the filtering accuracy. Therefore, it is preferable that the pulsation of pressure at the time of filtering is as low as possible.

The filtering speed is not particularly limited. However, in view of obtaining a chemical liquid having further improved effects of the present invention, the filtering speed is preferably equal to or higher than 1.0 L/min/m2, more preferably equal to or higher than 0.75 L/min/m², and even more preferably equal to or higher than 0.6 L/min/m².

For the filter, an endurable differential pressure for assuring the filter performance (assuring that the filter will not be broken) is set. In a case where the endurable differential pressure is high, by increasing the filtering pressure, the filtering speed can be increased. That is, it is preferable that the upper limit of the filtering speed is generally equal to or lower than 10.0 L/min/m² although the upper limit usually depends on the endurable differential pressure of the filter. Meanwhile, in a case where the filtering pressure is reduced, it is possible to efficiently reduce the amount of particle-like foreign substances or impurities dissolved in the substance to be purified, and to adjust the pressure according to the purpose.

In view of obtaining a chemical liquid having further improved effects of the present invention, the filtering pressure is preferably 0.001 to 1.0 MPa, more preferably 0.003 to 0.5 MPa, and even more preferably 0.005 to 0.3 MPa. Particularly, in a case where a filter having a small pore size is used, by increasing the filtering pressure, it is possible to efficiently reduce the amount of particle-like foreign substances or impurities dissolved in the substance to be purified. In a case where a filter having a pore size smaller than 20 nm is used, the filtering pressure is particularly preferably 0.005 to 0.3 MPa.

The smaller the pore size of the filtration filter, the lower the filtering speed. However, for example, in a case where a plurality of filtration filters of the same type are connected to each other in parallel, the filtering area is enlarged, and the filtering pressure is reduced. Therefore, in this way, the reduction in the filtering speed can be compensated.

It is more preferable that the filtering step has the following steps. In the filtering step, each of the following steps may be performed once or plural times. Furthermore, the order of the following steps is not particularly limited.
1. Particle removing step
2. Metal ion removing step
3. Organic impurity removing step
4. Ion exchange step

Hereinafter, each of the steps will be described.

### Particle Removing Step

It is preferable that the filtering step has a particle removing step. The particle removing step is a step of removing the particles in the substance to be purified by using a particle removing filter. The aspect of the particle removing filter is as described above as the filter that a filtering device in a manufacturing device comprising the filtering device includes in some cases.

### Metal Ion Removing Step

It is preferable that the filtering step has a metal ion removing step. As the metal ion removing step, a step of passing the substance to be purified through a metal ion adsorption filter is preferable. The method for passing the substance to be purified through the metal ion adsorption filter is not particularly limited, and examples thereof include a method of disposing a filtering device including a metal ion adsorption filter in the middle of a pipe line transferring the substance to be purified and passing the substance to be purified through the metal ion adsorption filter with or without applying pressure thereto.

The metal ion adsorption filter is as described above as the filter that a filtering device in a manufacturing device comprising the filtering device includes in some cases.

### Organic Impurity Removing Step

It is preferable that the filtering step has an organic impurity removing step. As the organic impurity removing step, a step of passing the substance to be purified through an organic impurity adsorption filter is preferable. The method for passing the substance to be purified through the organic impurity adsorption filter is not particularly limited, and examples thereof include a method of disposing a filtering device including an organic impurity adsorption filter in the middle of a pipe line transferring the substance to be purified and passing the organic solvent through the filtering device with or without applying pressure thereto.

The organic impurity adsorption filter is as described above as the filter that a filtering device in a manufacturing device comprising the filtering device includes in some cases.

### Ion Exchange Step

The filtering step may further have an ion exchange step.

As the ion exchange step, a step of passing the substance to be purified through an ion exchange unit is preferable. The method for passing the substance to be purified through the ion exchange unit is not particularly limited, and examples thereof include a method of disposing an ion exchange unit in the middle of a pipe line transferring the substance to be purified and passing the organic solvent through the ion exchange unit with or without applying pressure thereto.

As the ion exchange unit, known ion exchange units can be used without particular limitation. Examples of the ion exchange unit include an ion exchange unit including a tower-like container storing an ion exchange resin, an ion adsorption membrane, and the like.

Examples of an aspect of the ion exchange step include a step in which a cation exchange resin or an anion exchange resin provided as a single bed is used as an ion exchange resin, a step in which a cation exchange resin and an anion exchange resin provided as a dual bed are used as an ion exchange resin, and a step in which a cation exchange resin and an anion exchange resin provided as a mixed bed are used as an ion exchange resin.

In order to reduce the amount of moisture eluted from the ion exchange resin, as the ion exchange resin, it is preferable to use a dry resin which does not contain moisture as far as possible. As the dry resin, commercial products can be used, and examples thereof include 15JS-HG·DRY (trade name, dry cation exchange resin, moisture: equal to or smaller than 2%) and MSPS2-1·DRY (trade name, mixed bed resin, moisture: equal to or smaller than 10%) manufactured by ORGANO CORPORATION, and the like.

As another aspect of the ion exchange step, a step of using an ion adsorption membrane can be exemplified.

In a case where the ion adsorption membrane is used, a treatment can be performed at a high flow rate. The ion adsorption membrane is not particularly limited, and examples thereof include NEOSEPTA (trade name, manufactured by ASTOM Corporation), and the like.

It is preferable that the ion exchange step is performed after the distillation step described above. In a case where the ion exchange step is performed, it is possible to remove the impurities accumulated in the purification device in a case where the impurities leak or to remove substances eluted from piping made of stainless steel (SUS) or the like used as a transfer pipe line.

As an aspect of the filtering step that the preparation step has, for example, an aspect is suitable in which the manufacturing device comprises a filtering device which is connected to a tank through a pipe line and disposed such that a fluid can move between the tank and the filtering device through the pipe line, the filtering device includes at least one kind of filtering member selected from the group consisting of a filter for removing particles having a diameter equal to or smaller than 20 nm and a metal ion adsorption member (the filtering device preferably includes both the filter and the metal ion adsorption member), and the preparation step is a step of filtering an organic solvent by using the filtering member.

The metal ion adsorption member more preferably includes a metal ion adsorption filter capable of performing ion exchange, and the metal ion adsorption filter more preferably contains an acid group on the surface thereof.

### Other Steps

As long as the effects of the present invention are exhibited, the chemical liquid manufacturing method may include other steps. Those other steps are not particularly limited, and examples thereof include an electricity removing step.

### Electricity Removing Step

The electricity removing step is a step of removing electricity from the substance to be purified such that the charge potential of the substance to be purified is reduced.

As the electricity removing method, known electricity removing methods can be used without particular limitation. Examples of the electricity removing method include a method for bringing the substance to be purified into contact with a conductive material.

The contact time for which the substance to be purified is brought into contact with a conductive material is preferably 0.001 to 60 seconds, more preferably 0.001 to 1 second, and even more preferably 0.01 to 0.1 seconds. Examples of the conductive material include stainless steel, gold, platinum, diamond, glassy carbon, and the like.

Examples of the method for bringing the substance to be purified into contact with a conductive material include a method for disposing a grounded mesh formed of a conductive material in the interior of a pipe line and passing the substance to be purified through the mesh, and the like.

### Container

The chemical liquid may be temporarily stored in a container until the chemical liquid is used. As the container for storing the chemical liquid, known containers can be used without particular limitation.

As the container storing the chemical liquid, a container for manufacturing a semiconductor is preferable which has high internal cleanliness and hardly causes elution of impurities.

Examples of the usable container specifically include a “CLEAN BOTTLE” series manufactured by AICELLO CORPORATION, “PURE BOTTLE” manufactured by KODAMA PLASTICS Co., Ltd., and the like, but the container is not limited to these.

As the container, for the purpose of preventing mixing of impurities into the raw materials and/or the chemical liquid (contamination), it is preferable to use a multilayer bottle in which the liquid contact portion of the container has a 6-layer laminated structure formed of 6 kinds of resins or a multilayer bottle in which the liquid contact portion of the container has a 7-layer laminated structure formed of 6 kinds of resins. Examples of these containers include the containers described in JP2015-123351A, but the container is not limited to these.

It is preferable that the liquid contact portion of the container is formed of a nonmetallic material or stainless steel.

Examples of the nonmetallic material include the materials exemplified above as nonmetallic materials used in the liquid contact portion of the distillation column.

Particularly, in a case where a container in which the liquid contact portion is formed of a fluororesin among the above materials is used, the occurrence of a problem such as elution of an ethylene or propylene oligomer can be further inhibited than in a case where a container in which the liquid contact portion is formed of a polyethylene resin, a polypropylene resin, or a polyethylene-polypropylene resin is used.

Specific examples of the container in which the liquid contact portion is formed of a fluororesin include FluoroPure PFA composite drum manufactured by Entegris, Inc., and the like. Furthermore, it is possible to use the containers described on p. 4 in JP1991-502677A (JP-H03-502677A), p. 3 in WO2004/016526A, p. 9 and p. 16 in WO99/046309A, and the like. In a case where the nonmetallic material is used for the liquid contact portion, it is preferable to inhibit the elution of the nonmetallic material into the chemical liquid.

For the container, the liquid contact portion contacting the chemical liquid is preferably formed of stainless steel, and more preferably formed of electropolished stainless steel.

In a case where the chemical liquid is stored in such a container, it is more difficult for the impurity metal and/or the organic impurity to be eluted into the chemical liquid stored in the container.

The aspect of the stainless steel is as described above as the material of the liquid contact portion of the distillation column. The aspect of the electropolished stainless steel is as described above as well.

The Cr/Fe ratio in the stainless steel forming the liquid contact portion of the container is as described above as the Cr/Fe ratio in the liquid contact portion of the tank.

It is preferable that the interior of the aforementioned container is washed before the solution is stored into the container. As a liquid used for washing, the washing solution described above, the chemical liquid itself, or a liquid obtained by diluting the chemical liquid is preferable. After being manufactured, the chemical liquid may be bottled using a container such as a gallon bottle or a quart bottle, transported, and stored. The gallon bottle may be formed of a glass material or other materials.

In order to prevent the change of the components in the solution during storage, purging may be performed in the interior of the container by using an inert gas (nitrogen, argon, or the like) having a purity equal to or higher than 99.99995% by volume. Particularly, a gas with small moisture content is preferable. The temperature at the time of transport and storage may be room temperature. However, in order to prevent alteration, the temperature may be controlled within a range of −20° C. to 30° C.

### Clean Room

It is preferable that all of the manufacturing of the chemical liquid, the opening and/or washing of the container, the handling including storage of the solution, the treatment and analysis, and the measurement are performed in a clean room. It is preferable that the clean room meets the 14644-1 clean room standard. The clean room preferably meets any of International Organization for Standardization (ISO) class 1, ISO class 2, ISO class 3, or ISO class 4, more preferably meets ISO class 1 or ISO class 2, and even more preferably meets ISO class 1.

### Use of Chemical Liquid

The chemical liquid manufactured by the chemical liquid manufacturing method according to the above embodiment is preferably used for manufacturing semiconductors. Specifically, in a semiconductor device manufacturing process including a lithography step, an etching step, an ion implantation step, a peeling step, and the like, the chemical liquid is used for treating an organic substance after each step is finished or before the next step is started. Specifically, the chemical liquid is suitably used as a prewet solution, a developer, a rinsing solution, a peeling solution, and the like. For example, the chemical liquid can also be used for rinsing of edge line of semiconductor substrates before and after the coating with resist.

Furthermore, the chemical liquid can also be used as a diluent of a resin contained in a resist solution (which will be described later). That is, the chemical liquid can also be used as a solvent to be incorporated into an actinic ray-sensitive or radiation-sensitive composition.

The chemical liquid can also be suitably used for other uses in addition to the manufacturing of semiconductors. The chemical liquid can be used as a developer, a rinsing solution, and the like of polyimide, a resist for a sensor, a resist for a lens, and the like.

In addition, the chemical liquid can also be used as a solvent for medical uses or for washing. Particularly, the chemical liquid can be suitably used for washing containers, piping, substrates (for example, a wafer and glass), and the like.

Particularly, the chemical liquid manufactured by the chemical liquid manufacturing method according to the above embodiment is more preferably used for pre-wetting. That is, it is preferable that the chemical liquid manufactured by the chemical liquid manufacturing method according to the above embodiment is used as a prewet solution.

### Examples

Hereinafter, the present invention will be more specifically described based on examples. The materials, the amount and proportion of the materials used, the details of treatments, the procedure of treatments, and the like shown in the following examples can be appropriately modified as long as the gist of the present invention is maintained. Accordingly, the scope of the present invention is not limited to the following examples.

### Manufacturing of Chemical Liquid

In order to manufacture organic solvents relating to examples and a comparative example, the washing solutions and the organic solvents described in Table 1 were prepared. As each of the washing solutions and the organic solvents, a high-purity grade with purity equal to or higher than 99% by mass was used. The content (mass ppt, simply described as “ppt” in the table) of metals originally contained in the used washing solutions is shown in the column of “Total amount of metal”.

By using the purification device shown in FIG. 2, chemical liquids were purified. The purification device which was to be used for purifying each of the chemical liquids had been used for purifying different chemical liquids. That is, the contamination state of the purification device before washing varies among the examples and the comparative example.

Table 1 shows filters used for manufacturing chemical liquids of the examples and the comparative example. The abbreviation for each of the filters in Table 1 is as below. “First stage”, “Second stage”, and “Third stage” represent filters mounted on the filtering device 105 in FIG. 2 in this order from the pump 104 side.

IEX-PTFE (15 nm): 15 nm IEX PTFE manufactured by Entegris, Inc. (filter made of PTFE having a pore size of 15 nm including a base material having a sulfo group on the surface thereof, corresponding to a metal ion adsorption filter)

PTEE (12 nm): 12 nm PTFE manufactured by Entegris, Inc. (filter made of PTFE for removing particles having a diameter of 12 nm)

UPE (3 nm): 3 nm PE filter manufactured by Entegris, Inc. (filter manufactured by Entegris, Inc. for removing particles having a diameter of 3 nm)

The liquid contact portion of the tank 101 was formed of electropolished stainless steel. The content mass ratio of the Cr content to the Fe content in the stainless steel of the tank 101 used in each of the examples and the comparative example is described in the column of “Cr/Fe” in Table 1.

### Washing Method

The chemical liquid of each of the examples and the comparative example was manufactured by the following method.

First, each of the washing solutions described in Table 1 was supplied from the pipe line 203, and the supplied washing solution was distilled in the distillation column 201. The washing solution gasified in the distillation column 201 was liquefied in a condenser not shown in the drawing, passed through the pipe line 202, and stored in the tank 101 through the supply port 102. The volume of the tank 101 was 5,000 L, and the amount of the supplied washing solution was 1,500 L. Then, the washing solution was stirred for 1 hour by using a stirrer in the tank 101 not shown in the drawing. Thereafter, the stirrer was stopped, the valve 103 and the valve 106 were opened, the valve 107 was closed, and the pump 104 was operated such that the washing solution circulated in the manufacturing device 100.

Subsequently, by using a flow meter which was mounted on the supply pipe line 109 but is not shown in the drawing, the flow rate of the washing solution was measured. At a point in time when the cumulative flow rate of the washing solution from beginning of circulation became 5,000 L, the number of times of circulation washing was regarded as 1. The number of times of circulation washing in the step A was predetermined as the number of times described in the column of “Number of times of circulation washing” in Table 1. After the step A ended, the step B was performed.

### Measurement

After the washing was performed by the predetermined number of times of circulation washing (then number of times described in the column of “Number of times of circulation washing” in Table 1), a portion of the washing solution was drawn from the washing solution monitoring portion 112, and the density of particles contained in the washing solution and the like were measured by the following method. All of the following measurements were performed in a clean room that met the level equal to or lower than International Organization for Standardization (ISO) Class 2. In order to improve the measurement accuracy, at the time of measuring each component, in a case where the content of the component was found to be equal to or smaller than a detection limit by general measurement, the washing solution was concentrated by 1/100 in terms of volume for performing the measurement, and the content was calculated by converting the concentration into the content of the washing solution not yet being concentrated. These measurement conditions were also applied to the measurement of the content of impurity metals in the washing solution and the measurement of the content of organic impurities in the washing solution that will be described later.

### P₂₀ density and P₁₀₀ Density

The change in each of the P₂₀ density and the P₁₀₀ density was determined by the following method.

First, by using “CLEAN TRACK LITHIUS (trade name)” manufactured by Tokyo Electron Limited., a silicon wafer having a diameter of 300 mm (hereinafter, simply referred to as “wafer” as well in the present specification) was spin-coated with a measurement sample at 1,500 rpm. Then, the wafer was dried. Thereafter, the number of particles on the wafer was measured using “SP-5 (trade name)” manufactured by KLA-Tencor Corporation. The number of particles was counted for three groups of particles sorted according to the particle diameter.

Number of particles (Pm) having a particle diameter equal to or smaller than 20 nm

Number of particles having a particle diameter greater than 20 nm and equal to or smaller than 60 nm

Number of particles having a particle diameter greater than 60 nm and equal to or smaller than 100 nm.

From the number of particles, each of the P₂₀ density and the P₁₀₀ density (number of particles/cm²) of the particles having the respective particle diameters on the wafer was calculated.

Regarding the groups described above, the change in the P₁₀₀ density of the particles having a particle diameter greater than 20 nm and equal to or smaller than 100 nm equals the change in the density of the particles having a particle diameter greater than 20 nm and equal to or smaller than 60 nm (described as “P₂₀₋₆₀” in the table) plus the change in the density of particles having a particle diameter greater than 60 nm and equal to or smaller than 100 nm (described as “P₆₀₋₁₀₀” in the table). That is, the change in the P₁₀₀ density is expressed as the following equation.

Equation: change in P₁₀₀ density=change in P₂₀₋₆₀ density+change in P₆₀₋₁₀₀ density

As a result of the measurement, the change in the P₂₀ density was equal to or smaller than 0.5 particles/cm² in the examples. The change in the P₂₀ density measured at this time is described in the column of “P₂₀” in Table 1. Furthermore, the change in the P₂₀₋₆₀ density and the change in the P₆₀₋₁₀₀ density of the washing solution obtained in a case where the change in the P₂₀ density became equal to or smaller than 0.5 particles/cm² are described in the columns of “P₂₀₋₆₀” and “P₆₀₋₁₀₀” in Table 1 respectively.

### Measurement of Number of Particles (Coarse Particles) having Particle Diameter Greater than 100 Nm

The number of particles, which had a particle diameter greater than 100 nm, in the washing solution was measured by the following method. By using a light scattering-type liquid-borne particle counter (manufactured by RION Co., Ltd., model number: KS-18F, light source: semiconductor laser-excited solid-state laser (wavelength: 532 nm, rated power: 500 mW), flow rate: 10 mL/min, the measurement principle is based on a dynamic light scattering method), the number of particles having a size equal to or greater than 100 nm contained in 1 mL of the washing solution is counted 5 times, and the average thereof was adopted as the number of coarse particles.

The light scattering-type liquid-borne particle counter was used for measurement after being calibrated using a Polystyrene Latex (PSL) standard particle solution.

As a result of the measurement, in all of the examples, the number of coarse particles in the washing solution was equal to or smaller than 5/mL.

### Content of Specific Impurity Metals in Washing Solution having Been Used for Circulation Washing

The content (mass ppt, simply described as “ppt” in the table) of specific impurity metals in the washing solution in which the change of the P₂₀ density in the washing solution became equal to or smaller than 0.5 particles/cm² was measured by the following method. The results are shown in the column of “Content of specific impurity metals” in Table 1.

For the measurement, Agilent 8800 triple quadrupole ICP-MS (for semiconductor analysis, option #200) was used. According to this measurement device, the content of the specific impurity metals as particles in each of the measurement samples and the content of specific impurity metals (for example, ions and the like) other than the above can be separately measured.

### Measurement Condition

As a sample introduction system, a quartz torch, a coaxial perfluoroalkoxyalkane (PFA) nebulizer (for self-suction), and a platinum interface cone were used. The measurement parameters of cool plasma conditions are as below.
Output of Radio Frequency (RF) (W): 600
Flow rate of carrier gas (L/min): 0.7
Flow rate of makeup gas (L/min): 1
Sampling depth (mm): 18

### Content of Organic Impurity Having Boiling Point Equal to or Higher Than 250° C. in Washing Solution

The content (mass ppm, simply described as “ppm” in the table) of the organic impurity having a boiling point equal to or higher than 250° C. in the washing solution in which the change in the P20 density in the washing solution became equal to or smaller than 0.5 particles/cm² was measured using a gas chromatography mass spectrometer (trade name “GCMS-2020”,manufactured by Shimadzu Corporation, the measurement conditions were as described below). From the obtained measurement results, the organic impurity having a boiling point equal to or higher than 250° C. was sorted out of the organic impurities, and the content thereof was determined as well. The results are shown in the column of “Content of organic impurity” in Table 1.

### Measurement Condition

Capillary column: InertCap 5MS/NP 0.25 mml.D.×30 m df=0.25 μm
Sample introduction method: split 75 kPa constant pressure
Vaporizing chamber temperature: 230° C.
Column oven temperature: 80° C. (2 min)−500° C. (13 min) heating rate 15° C./min
Carrier gas: helium
Septum purge flow rate: 5 mL/min
Split ratio: 25:1
Interface temperature: 250° C.
Ion source temperature: 200° C.
Measurement mode: Scan m/z=85˜500
Amount of sample introduced: 1 μL

### Manufacturing of Chemical Liquid

At a point in time when the density of particles having a diameter equal to or smaller than 20 nm in the washing solution became equal to or lower than 0.5 particles/cm², the valve 106 was closed, and the valve 107 was opened such that the washing solution was discharged out of the manufacturing device.

Then, the valve 103 was closed, and from the supply port 102 of the tank 101, the organic solvent as a raw material of the chemical liquid of each of the examples and the comparative example was supplied. The amount of the supplied chemical liquid was 1,000 L. Subsequently, the valve 103 and the valve 107 were opened, and the pump 104 was operated such that the organic solvent flowed into the filtering device 105 through the valve 103 and the pump 104. By filtering the organic solvent, a chemical liquid was prepared, and the chemical liquid was collected from the container 108.

### Hansen Solubility Parameters

The hydrogen bond element, the dispersion element, and the dipole-dipole force element as Hansen solubility parameters of each of the washing solutions and the organic solvents were calculated using Hansen Solubility Parameter in Practice (HSPiP). From the calculated values, a contribution rate of each of Hansen solubility parameters was determined. Then, a difference between the contribution rate of Hansen solubility parameters of the washing solution and the contribution rate of Hansen solubility parameters of the organic solvent was determined. The difference is shown in Table 1. The calculation results are described in the column of “HP”.

### Evaluation of Defect Inhibition Performance of Chemical Liquid

The defect inhibition performance of the chemical liquid was evaluated by the following method.

First, by using “CLEAN TRACK LITHIUS (trade name)” manufactured by Tokyo Electron Limited., a silicon wafer having a diameter of 300 mm (hereinafter, simply referred to as “wafer” as well in the present specification) was spin-coated with the chemical liquid at 1,500 rpm, and then dried. Thereafter, the number of defects (having a size of 20 to 25 nm) on the wafer was measured using “SP-5 (trade name)” manufactured by KLA-Tencor Corporation. According to the following standards, the defect inhibition performance was evaluated. The results are shown in the column of “Defect inhibition performance” in Table 1.

AA: The number of defects was less than 50.

A: The number of defects was equal to or greater than 50 and less than 80.

B: The number of defects was equal to or greater than 80 and less than 100.

C: The number of defects was equal to or greater than 100 and less than 150.

D: The number of defects was equal to or greater than 150 and less than 200.

E: The number of defects was equal to or greater than 200.

TABLE 1

| | | Total | | | | Number of | | | |
|---|---|---|---|---|---|---|---|---|---|
| | | amount of | | | | times of | | | |
| | Washing | metal | Organic | | | circulation | Filter | | |
| Table 1-1 | solution | (ppt) | solvent | HP | Cr/Fe | washing | First stage | Second stage | Third stage |
| Example 1 | PGMEA | >100 | PGMEA | 0 | 0.6 | 5 | IEX-PTFE (15 nm) | PTFE (12 nm) | |
| Example 2 | PGMEA | >100 | PGMEA | 0 | 1 | 5 | IEX-PTFE (15 nm) | PTFE (12 nm) | |
| Example 3 | PGMEA | >100 | PGMEA | 0 | 1.5 | 5 | IEX-PTFE (15 nm) | PTFE (12 nm) | |
| Example 4 | PGMEA | >100 | PGMEA | 0 | 2 | 5 | IEX-PTFE (15 nm) | PTFE (12 nm) | |
| Example 5 | PGMEA | >100 | PGMEA | 0 | 2.5 | 5 | IEX-PTFE (15 nm) | PTFE (12 nm) | |
| Example 6 | PGMEA | >100 | PGMEA | 0 | 3 | 5 | IEX-PTFE (15 nm) | PTFE (12 nm) | |
| Example 7 | PGMEA | >100 | PGMEA | 0 | 2 | 5 | IEX-PTFE (15 nm) | PTFE (12 nm) | |
| Example 8 | PGMEA | >100 | PGMEA | 0 | 2 | 5 | IEX-PTFE (15 nm) | PTFE (12 nm) | |
| Example 9 | PGMEA | >100 | PGMEA | 0 | 2 | 5 | IEX-PTFE (15 nm) | PTFE (12 nm) | |
| Example 10 | PGMEA | >100 | PGMEA | 0 | 2 | 5 | IEX-PTFE (15 nm) | PTFE (12 nm) | |
| Example 11 | PGMEA | >100 | PGMEA | 0 | 2 | 5 | IEX-PTFE (15 nm) | PTFE (12 nm) | |
| Example 12 | PGMEA | >100 | PGMEA | 0 | 2 | 5 | IEX-PTFE (15 nm) | PTFE (12 nm) | |
| Example 13 | PGMEA | >100 | PGMEA | 0 | 2 | 5 | IEX-PTFE (15 nm) | PTFE (12 nm) | |
| Example 14 | PGMEA | >100 | PGMEA | 0 | 2 | 5 | IEX-PTFE (15 nm) | PTFE (12 nm) | |
| Example 15 | PGMEA | >100 | PGMEA | 0 | 2 | 5 | IEX-PTFE (15 nm) | PTFE (12 nm) | |
| Example 16 | PGMEA | >100 | PGMEA | 0 | 2 | 5 | IEX-PTFE (15 nm) | PTFE (12 nm) | |
| Example 17 | PGMEA | >100 | PGMEA | 0 | 2 | 5 | IEX-PTFE (15 nm) | PTFE (12 nm) | |
| Example 18 | PGMEA | >100 | PGMEA | 0 | 2 | 5 | IEX-PTFE (15 nm) | PTFE (12 nm) | |
| Example 19 | PGMEA | >100 | PGMEA | 0 | 2 | 5 | IEX-PTFE (15 nm) | PTFE (12 nm) | |
| Example 20 | PGMEA | >100 | PGMEA | 0 | 2 | 2 | IEX-PTFE (15 nm) | PTFE (12 nm) | |
| Example 21 | PGMEA | >100 | PGMEA | 0 | 2 | 20 | IEX-PTFE (15 nm) | PTFE (12 nm) | |
| Example 22 | PGMEA | >100 | PGMEA | 0 | 2 | 5 | IEX-PTFE (15 nm) | PTFE (12 nm) | UPE (3 nm) |
| Example 23 | PGMEA | >100 | PGMEA | 0 | 2 | 5 | PTFE (12 nm) | UPE (3 nm) | |
| Example 24 | NMP | >100 | PGMEA | 16 | 2 | 5 | IEX-PTFE (15 nm) | PTFE (12 nm) | UPE (3 nm) |
| Example 25 | PGME | >100 | PGMEA | 16 | 2 | 5 | IEX-PTFE (15 nm) | PTFE (12 nm) | UPE (3 nm) |
| Example 26 | nBA | >100 | PGMEA | 5 | 2 | 5 | IEX-PTFE (15 nm) | PTFE (12 nm) | UPE (3 nm) |
| Example 27 | PC | >100 | MIBC | 31 | 2 | 5 | IEX-PTFE (15 nm) | PTFE (12 nm) | UPE (3 nm) |
| Example 28 | nBA | >100 | nBA | 0 | 2 | 5 | IEX-PTFE (15 nm) | PTFE (12 nm) | UPE (3 nm) |
| Example 29 | PGME | >100 | PGME | 0 | 2 | 5 | IEX-PTFE (15 nm) | PTFE (12 nm) | UPE (3 nm) |
| Example 30 | CyHe | >100 | CyHe | 0 | 2 | 5 | IEX-PTFE (15 nm) | PTFE (12 nm) | UPE (3 nm) |
| Example 31 | GBL | >100 | GBL | 0 | 2 | 5 | IEX-PTFE (15 nm) | PTFE (12 nm) | UPE (3 nm) |
| Example 32 | MIBC | >100 | MIBC | 0 | 2 | 5 | IEX-PTFE (15 nm) | PTFE (12 nm) | UPE (3 nm) |
| Example 33 | EL | >100 | EL | 0 | 2 | 5 | IEX-PTFE (15 nm) | PTFE (12 nm) | UPE (3 nm) |
| Example 34 | DMSO | >100 | DMSO | 0 | 2 | 5 | IEX-PTFE (15 nm) | PTFE (12 nm) | UPE (3 nm) |
| Example 35 | iAA | >100 | iAA | 0 | 2 | 5 | IEX-PTFE (15 nm) | PTFE (12 nm) | UPE (3 nm) |
| Example 36 | PGMEA/ | >100 | PGMEA/ | 0 | 2 | 5 | IEX-PTFE (15 nm) | PTFE (12 nm) | UPE (3 nm) |
| | PGME | | PGME | | | | | | |
| | (v/v = 7/3) | | (v/v = 7/3) | | | | | | |
| Example 37 | HBM | >100 | HBM | 0 | 2 | 5 | IEX-PTFE (15 nm) | PTFE (12 nm) | UPE (3 nm) |
| Example 38 | MEK | >100 | MEK | 0 | 2 | 5 | IEX-PTFE (15 nm) | PTFE (12 nm) | UPE (3 nm) |
| Example 39 | PC | >100 | PC | 0 | 2 | 5 | IEX-PTFE (15 nm) | PTFE (12 nm) | UPE (3 nm) |
| Example 40 | CyPe | >100 | CyPe | 0 | 2 | 5 | IEX-PTFE (15 nm) | PTFE (12 nm) | UPE (3 nm) |
| Example 41 | nBA | >100 | nBA | 0 | 0.3 | 5 | IEX-PTFE (15 nm) | PTFE (12 nm) | UPE (3 nm) |
| Example 42 | nBA | >100 | nBA | 0 | 3.8 | 5 | IEX-PTFE (15 nm) | PTFE (12 nm) | UPE (3 nm) |
| Comparative | nBA | >100 | nBA | 0 | 3 | 5 | IEX-PTFE (15 nm) | PTFE (12 nm) | UPE (3 nm) |
| Example 1 | | | | | | | | | |

| | P₂₀ | P₂₀₋₆₀ | P₆₀₋₁₀₀ | Content of specific impurity metal | | | | Content of | |
|---|---|---|---|---|---|---|---|---|---|
| | (number of | (number of | (number of | Fe | Cr | Pb | Ni | organic impurity | Defect inhibition |
| Table 1-2 | particles/cm²) | particles/cm²) | particles/cm²) | (ppt) | (ppt) | (ppt) | (ppt) | (ppm) | performance |
| Example 1 | 0.3 | 0.08 | 0.01 | 0.002 | 0.001 | 0.001 | 0.005 | 0.08 | B |
| Example 2 | 0.3 | 0.05 | 0.01 | 0.004 | 0.001 | 0.001 | 0.002 | 0.1 | A |
| Example 3 | 0.3 | 0.08 | 0.01 | 0.001 | 0.001 | 0.002 | 0.002 | 0.1 | A |
| Example 4 | 0.3 | 0.04 | 0.01 | 0.002 | 0.001 | 0.002 | 0.003 | 0.06 | A |
| Example 5 | 0.3 | 0.06 | 0.01 | 0.003 | 0.002 | 0.001 | 0.002 | 0.1 | A |
| Example 6 | 0.3 | 0.08 | 0.01 | 0.002 | 0.001 | 0.001 | 0.003 | 0.09 | A |
| Example 7 | 0.05 | 0.01 | 0.002 | 0.003 | 0.001 | 0.002 | 0.002 | 0.1 | AA |
| Example 8 | 0.45 | 0.18 | 0.1 | 0.002 | 0.001 | 0.002 | 0.003 | 0.12 | B |
| Example 9 | 0.3 | 0.08 | 0.01 | <0.001 | <0.001 | <0.001 | <0.001 | 0.06 | C |
| Example 10 | 0.3 | 0.08 | 0.01 | 0.03 | 0.01 | 0.01 | 0.02 | 0.12 | A |
| Example 11 | 0.3 | 0.08 | 0.01 | 0.3 | 0.1 | 0.1 | 0.2 | 0.12 | B |
| Example 12 | 0.3 | 0.08 | 0.01 | 6 | 2 | 2 | 4 | 0.1 | B |
| Example 13 | 0.3 | 0.08 | 0.01 | 24 | 8 | 8 | 16 | 0.12 | C |
| Example 14 | 0.3 | 0.08 | 0.01 | 35 | 11 | 11 | 21 | 0.1 | D |
| Example 15 | 0.3 | 0.08 | 0.01 | 0.001 | 0.001 | 0.002 | 0.002 | 0.005 | A |
| Example 16 | 0.3 | 0.08 | 0.01 | 0.004 | 0.002 | 0.001 | 0.002 | 0.08 | B |
| Example 17 | 0.3 | 0.08 | 0.01 | 0.002 | 0.001 | 0.002 | 0.005 | 1 | B |
| Example 18 | 0.3 | 0.08 | 0.01 | 0.003 | 0.001 | 0.002 | 0.002 | 20 | C |
| Example 19 | 0.3 | 0.08 | 0.01 | 0.003 | 0.002 | 0.001 | 0.002 | 120 | D |
| Example 20 | 0.3 | 0.08 | 0.01 | 0.001 | 0.002 | 0.002 | 0.002 | 0.06 | B |
| Example 21 | 0.02 | 0.01 | 0.002 | 0.004 | 0.001 | 0.002 | 0.003 | 0.1 | AA |
| Example 22 | 0.3 | 0.01 | 0.002 | 0.002 | 0.001 | 0.002 | 0.002 | 0.12 | AA |
| Example 23 | 0.3 | 0.08 | 0.01 | 0.003 | 0.002 | 0.001 | 0.005 | 0.1 | B |
| Example 24 | 0.02 | 0.08 | 0.01 | 0.001 | 0.001 | 0.002 | 0.002 | 0.12 | A |
| Example 25 | 0.03 | 0.08 | 0.01 | 0.002 | 0.001 | 0.001 | 0.003 | 0.1 | A |
| Example 26 | 0.03 | 0.01 | 0.002 | 0.003 | 0.001 | 0.001 | 0.002 | 0.06 | AA |
| Example 27 | 0.03 | 0.08 | 0.01 | 0.003 | 0.001 | 0.003 | 0.002 | 0.1 | C |
| Example 28 | 0.03 | 0.01 | 0.001 | 0.002 | 0.001 | 0.001 | 0.005 | 0.1 | AA |
| Example 29 | 0.04 | 0.01 | 0.002 | 0.001 | 0.002 | 0.002 | 0.002 | 0.12 | AA |
| Example 30 | 0.03 | 0.01 | 0.003 | 0.002 | 0.001 | 0.001 | 0.003 | 0.09 | AA |
| Example 31 | 0.02 | 0.01 | 0.002 | 0.003 | 0.002 | 0.001 | 0.002 | 0.06 | AA |
| Example 32 | 0.02 | 0.01 | 0.002 | 0.001 | 0.001 | 0.001 | 0.003 | 0.1 | AA |
| Example 33 | 0.03 | 0.01 | 0.002 | 0.002 | 0.001 | 0.002 | 0.002 | 0.1 | AA |
| Example 34 | 0.03 | 0.01 | 0.001 | 0.002 | 0.001 | 0.001 | 0.002 | 0.09 | AA |
| Example 35 | 0.03 | 0.01 | 0.003 | 0.004 | 0.001 | 0.001 | 0.003 | 0.1 | AA |
| Example 36 | 0.02 | 0.01 | 0.004 | 0.002 | 0.002 | 0.001 | 0.002 | 0.06 | AA |
| Example 37 | 0.04 | 0.01 | 0.002 | 0.003 | 0.001 | 0.001 | 0.002 | 0.1 | AA |
| Example 38 | 0.05 | 0.01 | 0.001 | 0.002 | 0.001 | 0.002 | 0.002 | 0.1 | AA |
| Example 39 | 0.02 | 0.01 | 0.003 | 0.002 | 0.002 | 0.001 | 0.003 | 0.06 | AA |
| Example 40 | 0.03 | 0.01 | 0.002 | 0.003 | 0.001 | 0.001 | 0.002 | 0.1 | AA |
| Example 41 | 0.3 | 0.08 | 0.01 | 0.004 | 0.001 | 0.001 | 0.002 | 0.09 | D |
| Example 42 | 0.3 | 0.08 | 0.01 | 0.002 | 0.001 | 0.001 | 0.002 | 0.1 | D |
| Comparative | 0.8 | 0.5 | 0.3 | 0.003 | 0.001 | 0.001 | 0.002 | 0.1 | E |
| Example 1 | | | | | | | | | |

In Table 1, “<” means that the amount is less than the numerical values listed on the right side of “<”, “>” means that the amount is greater than the numerical values listed on the right side of “>”, and “PGMEA/PGME (v/v=7/3)” means that PGMEA and PGME were mixed together at a volume ratio of 7:3.

The measurement results, the manufacturing conditions, and the like relating to the chemical liquid of Example 1 are shown in Table 1 divided into Table 1-1 and Table 1-2. That is, in Table 1-1 and Table 1-2, all of the results and the like described in the rows for Example 1 relate to the chemical liquid of Example 1. The same is true for the chemical liquid of each of the examples and the comparative example.

Furthermore, in Table 1, “v/v” represents a volume ratio between components of a mixture.

As is evident from the results shown in Table 1, the chemical liquid of each of the examples, which was manufactured by the chemical liquid manufacturing method having the setup step, which has the step A and the step B and in which the step A and the step B are repeatedly performed until the condition 1 is satisfied, and the preparation step had an excellent defect inhibition performance. In contrast, the chemical liquid of the comparative example did not have the desired defect inhibition performance.

As is evident from the results shown in Table 1, the chemical liquid manufactured by the chemical liquid manufacturing method of Example 7, in which the step A and the step B were repeatedly performed in the setup step until the additional condition 2 was further satisfied, had a defect inhibition performance better than that of the chemical liquid of Example 4.

As is evident from the results shown in Table 1, in the chemical liquid manufactured by the chemical liquid manufacturing method of Example 26, in which the manufacturing device comprised a tank, the liquid contact portion in the tank was formed of electropolished stainless steel, and the content mass ratio of the Cr content to the Fe content in the liquid contact portion was higher than 0.5 and less than 3.5, the Fe content tended to be smaller than in the chemical liquid of Example 41, and the chemical liquid of Example 26 had a further improved defect inhibition performance. In the chemical liquid manufactured by the chemical liquid manufacturing method of Example 26, the content mass ratio of the Cr content to the Fe content was less than 3.5. Therefore, the content of particles such as P20 and P₁₀₀ in the manufactured chemical liquid tended to be small. As a result, the chemical liquid of Example 26 had a further improved defect inhibition performance. Presumably, in a case where the content mass ratio of the Cr content to the Fe content is higher than 3.5, the surface of the liquid contact portion in the tank may tend to be rough and may be easily corroded, the exfoliation of the liquid contact portion and the like may easily occur, and accordingly, the chemical liquid of Example 26 may have a further improved defect inhibition performance.

As is evident from the results shown in Table 1, the chemical liquid manufactured by the chemical liquid manufacturing method of Example 4, in which the step A and the step B were repeatedly performed in the setup step until the additional condition 3 was further satisfied, had a defect inhibition performance better than that of the chemical liquids of Example 9 and Example 13. Presumably, in a case where the content of the specific impurity metals is equal to or smaller than a predetermined range, the occurrence of a defect caused by the specific impurity metals may be inhibited, and in a case where the content of the specific impurity metals is equal to or greater than a predetermined range, the specific impurity metals may be easily aggregated with each other. It is considered that as a result, the occurrence of a defect may be inhibited, and the chemical liquid of Example 4 may have an excellent defect inhibition performance.

As is evident from the results shown in Table 1, the chemical liquid manufactured by the chemical liquid manufacturing method of Example 15, in which the step A and the step B were repeatedly performed in the setup step until the additional condition 4 was further satisfied, had a defect inhibition performance better than that of the chemical liquid of Example 18.

As is evident from the results shown in Table 1, the chemical liquid manufactured by the chemical liquid manufacturing method of Example 4, in which a manufacturing device comprising a filtering device having a metal ion adsorption member as a filtering member was used, had a defect inhibition performance better than that of the chemical liquid of Example 23. Presumably, in a case where the manufacturing device comprising a filtering device having a metal ion adsorption member is used, the total content of the impurity metals (particularly, the content of metal ions) in the chemical liquid may be reduced, and hence the chemical liquid of Example 4 may have an excellent defect inhibition performance.

The chemical liquid manufactured by the chemical liquid manufacturing method of Example 7, in which the difference between the contribution rate of Hansen solubility parameters of the washing solution and the contribution rate of Hansen solubility parameters of the organic solvent was 0 to 30, had a defect inhibition performance better than that of the chemical liquid of Example 22. Presumably, in a case where the organic solvent as a raw material of the chemical liquid is introduced into the manufacturing device after washing the manufacturing device, the contribution rates of Hansen solubility parameters of the organic solvent and the washing solution may become closer to each other, solvent shock may hardly occur, and hence the chemical liquid of Example 7 had an excellent defect inhibition performance.

### EXPLANATION OF REFERENCES

100, 200: manufacturing device
101: tank
102: supply port
103, 106, 107: valve
104: pump
105: filtering device
108: container
109: supply pipe line
110: circulation pipe line
111: discharge portion
112: washing solution monitoring portion
113: pipe line
201: distillation column
202, 203, 204: pipe line
205, 206, 207: valve

What is claimed is:

1. A chemical liquid manufacturing method for manufacturing a chemical liquid containing an organic solvent by using a manufacturing device, the method comprising:
a setup step having a step A of washing the manufacturing device by using a washing solution and a step B of extracting the washing solution from the manufacturing device; and
a preparation step of preparing the chemical liquid in the manufacturing device,
wherein in the setup step, the step A and the step B are repeatedly performed until the washing solution extracted from the manufacturing device satisfies the following condition 1 after the step A and the step B,
condition 1: in a case where a substrate is coated with the washing solution, a change in density of particles, which have a particle diameter equal to or smaller than 20 nm, on the substrate before and after the coating with the washing solution is equal to or smaller than 0.5 particles/cm².

2. The chemical liquid manufacturing method according to claim 1,
wherein in the setup step, the step A and the step B are repeatedly performed until the washing solution extracted from the manufacturing device further satisfies the following additional condition 2,
additional condition 2: in a case where a substrate is coated with the washing solution, a change in density of particles, which have a particle diameter greater than 20 nm and equal to or smaller than 100 nm, on the substrate before and after the coating with the washing solution is equal to or smaller than 0.04 particles/cm².

3. The chemical liquid manufacturing method according to claim 1,
wherein the manufacturing device comprises a tank,
a liquid contact portion in the tank is formed of electropolished stainless steel, and
a content mass ratio of a content of Cr to a content of Fe in the liquid contact portion is higher than 0.5 and lower than 3.5.

4. The chemical liquid manufacturing method according to claim 1,
wherein in the setup step, the step A and the step B are repeatedly performed until the washing solution extracted from the manufacturing device further satisfies the following additional condition 3,
additional condition 3: in the washing solution, a content of each of impurity metals containing Fe, Cr, Pb, and Ni is 0.001 to 10 mass ppt.

5. The chemical liquid manufacturing method according to claim 1,
wherein in the setup step, the step A and the step B are repeatedly performed until the washing solution extracted from the manufacturing device further satisfies the following additional condition 4,
additional condition 4: in the washing solution, a content of an organic impurity having a boiling point equal to or higher than 250° C. is 0.001 to 10 mass ppm.

6. The chemical liquid manufacturing method according to claim 5, wherein the organic impurity contains at least one kind of compound selected from the group consisting of Formulae (1) to (7).

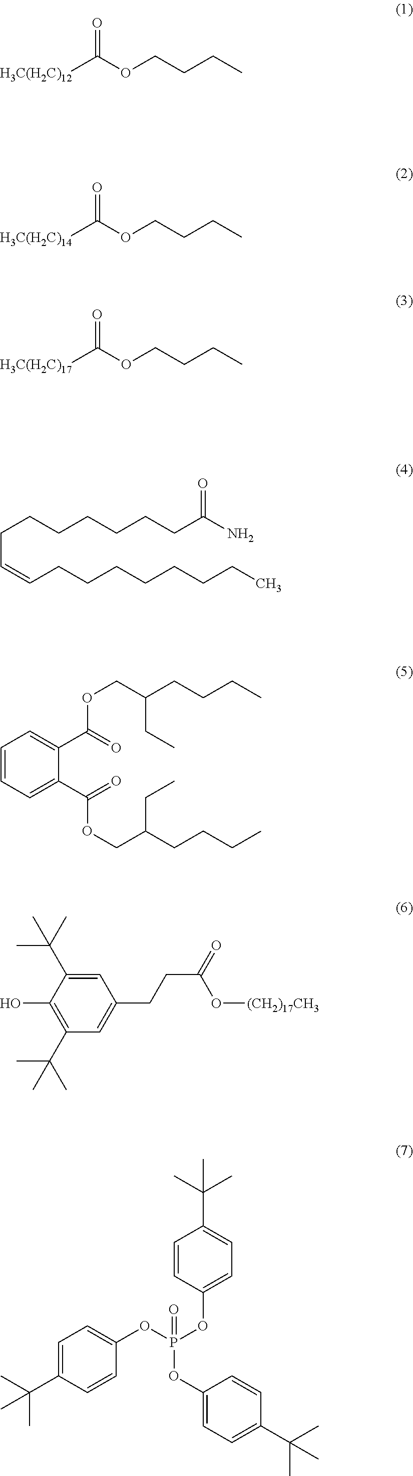

7. The chemical liquid manufacturing method according to claim 1,
wherein the manufacturing device comprises a filtering device,
the washing solution having been used in the step A is filtered through the filtering device at the time of repeatedly performing the step A and the step B in the setup step, and the filtered washing solution is reused in a new step A.

8. The chemical liquid manufacturing method according to claim 7,
wherein the filtering device includes at least one kind of filtering member selected from the group consisting of a filter for removing particles having a diameter equal to or smaller than 20 nm and a metal ion adsorption member.

9. The chemical liquid manufacturing method according to claim 8,
wherein the filtering member includes a filter for removing particles having a diameter equal to or smaller than 20 nm and a metal ion adsorption member.

10. The chemical liquid manufacturing method according to claim 8,
wherein the metal ion adsorption member includes a metal ion adsorption filter capable of performing ion exchange, and
the metal ion adsorption filter contains an acid group on a surface thereof.

11. The chemical liquid manufacturing method according to claim 1,
wherein a difference between a contribution rate of Hansen solubility parameters of the washing solution and a contribution rate of Hansen solubility parameters of the organic solvent is 0 to 30.

12. The chemical liquid manufacturing method according to claim 1,
wherein the chemical liquid is at least one kind of chemical liquid selected from the group consisting of a prewet solution, a developer, and a solvent contained in an actinic ray-sensitive or radiation-sensitive composition.

13. A chemical liquid manufacturing device for manufacturing a chemical liquid containing an organic solvent, the device comprising:
a tank which stores the organic solvent;
a filtering portion which is connected to the tank through a supply pipe line and filters the organic solvent discharged from the tank;
a circulation pipe line through which the organic solvent discharged from the filtering portion is stored in the tank;
a discharge portion which is provided in the circulation pipe line and discharges the chemical liquid; and
a washing solution monitoring portion which is provided in at least one site selected from the group consisting of the tank, the supply pipe line, and the circulation pipe line so as to extract at least a portion of a washing solution for washing the manufacturing device.

14. The chemical liquid manufacturing method according to claim 2,
wherein the manufacturing device comprises a tank,
a liquid contact portion in the tank is formed of electropolished stainless steel, and
a content mass ratio of a content of Cr to a content of Fe in the liquid contact portion is higher than 0.5 and lower than 3.5.

15. The chemical liquid manufacturing method according to claim 2,
wherein in the setup step, the step A and the step B are repeatedly performed until the washing solution extracted from the manufacturing device further satisfies the following additional condition 3,
additional condition 3: in the washing solution, a content of each of impurity metals containing Fe, Cr, Pb, and Ni is 0.001 to 10 mass ppt.

16. The chemical liquid manufacturing method according to claim 3,
wherein in the setup step, the step A and the step B are repeatedly performed until the washing solution extracted from the manufacturing device further satisfies the following additional condition 3,
additional condition 3: in the washing solution, a content of each of impurity metals containing Fe, Cr, Pb, and Ni is 0.001 to 10 mass ppt.

17. The chemical liquid manufacturing method according to claim 2,
wherein in the setup step, the step A and the step B are repeatedly performed until the washing solution extracted from the manufacturing device further satisfies the following additional condition 4,
additional condition 4: in the washing solution, a content of an organic impurity having a boiling point equal to or higher than 250° C. is 0.001 to 10 mass ppm.

18. The chemical liquid manufacturing method according to claim 3,
wherein in the setup step, the step A and the step B are repeatedly performed until the washing solution extracted from the manufacturing device further satisfies the following additional condition 4,
additional condition 4: in the washing solution, a content of an organic impurity having a boiling point equal to or higher than 250° C. is 0.001 to 10 mass ppm.

19. The chemical liquid manufacturing method according to claim 4,
wherein in the setup step, the step A and the step B are repeatedly performed until the washing solution extracted from the manufacturing device further satisfies the following additional condition 4,
additional condition 4: in the washing solution, a content of an organic impurity having a boiling point equal to or higher than 250° C. is 0.001 to 10 mass ppm.

20. The chemical liquid manufacturing method according to claim 2,
wherein the manufacturing device comprises a filtering device,
the washing solution having been used in the step A is filtered through the filtering device at the time of repeatedly performing the step A and the step B in the setup step, and
the filtered washing solution is reused in a new step A.
